(19) United States
(12) Patent Application Publication
(10) Pub. No.: US 2024/0376347 A1
(43) Pub. Date: Nov. 14, 2024

(54) CURABLE HOT MELT ORGANOPOLYSILOXANE COMPOSITION, CURED PRODUCT THEREOF AND METHOD FOR PRODUCING FILM, ETC. COMPRISING SAME

(71) Applicant: DOW TORAY CO., LTD., Shinagawa-Ku, Tokyo (JP)

(72) Inventors: Yuki YOKOUCHI, Ichihara-shi, Chiba (JP); Tomohiro IIMURA, Ichihara-shi, Chiba (JP)

(21) Appl. No.: 18/691,858

(22) PCT Filed: Sep. 8, 2022
(86) PCT No.: PCT/JP2022/033707

§ 371 Date: Mar. 13, 2024

(30) Foreign Application Priority Data
Sep. 14, 2021 (JP) 2021-149269

(51) Int. Cl. C09J 7/35; C09J 5/06; H01L 21/56

(52) U.S. Cl. CPC C09J 7/35; C09J 5/06; H01L 21/56; C09J 2203/326; C09J 2301/304; C09J 2301/416

(57) ABSTRACT

Provided is a hot-melt silicone composition that can be cured at various temperatures, that enables the design of the pressure-sensitive adhesive strength of a resulting cured product to a base material over a wide range, that has excellent transparency and yellowing resistance, and that has excellent handling workability. The composition comprises (A) 1 to 50 parts by mass of a chain organopolysiloxane having two or more alkenyl groups in a molecule, (B) 50 to 99 parts by mass of an MQ organopolysiloxane resin in which the molar ratio of M units to 1 mol of Q units is in the range of 0.5 to 2.0, and (C) 0.1 to 10 parts by mass of a radical polymerization initiator. Optionally, the composition comprises (D) another radical reactive component. The amount of component (B) is 50 mass % or more with respect to the total mass of the solid fraction of the composition.

### TECHNICAL FIELD

The present invention relates to: a hot-melt curable organopolysiloxane composition; and a sealing and adhering technique for a semiconductor or the like using the composition.

### BACKGROUND ART

Curable silicone compositions are cured to form cured products having excellent heat resistance, cold resistance, electrical insulation, weather resistance, water repellency, and transparency, and thus are utilized in a wide range of industrial fields. Cured products of such curable silicone compositions are hardly discolored as compared with other organic materials, and physical properties are less deteriorated, and thus are also suitable as sealing agents for optical materials and semiconductor devices.

The present patent applicants disclose in Patent Document 1, for example, a heat-curable hot-melt silicone composition. Specifically, Patent Document 1 discloses a curable hot-melt composition that uses an alkenyl group-containing organopolysiloxane with a high amount of phenyl groups as a main agent and cures by a hydrosilylation reaction. Herein, a curing agent disclosed in Patent Document 1 is a hydrosilylation reaction catalyst for heat curing reactions that require a high temperature exceeding 150° C.

On the other hand, in recent years, demand for optical devices and optical semiconductor devices using a resin member with low heat resistance has been expanding due to the need for functionality and reduced weight. In addition, there has been a growing trend toward lower energy consumption in manufacturing processes in recent years. Increasingly, these processes require photocurable materials that are cured by high-energy beam irradiation of UV rays or the like, which do not require high temperatures. However, as described above, conventional hot-melt silicone compositions have high curing temperatures that are practicable in sealing processes and the like, which may cause deformation and degradation of an organic resin with low heat resistance. Moreover, it is difficult to achieve a sufficient curing reaction rate and cured products at low temperatures, including room temperature.

On the other hand, to meet the demand for low temperature curing, the applicants have proposed in Patent Document 2 an active energy beam-curable hot-melt silicone composition that uses a thiol-ene reaction. Although the composition is superior from the perspective of being quickly curable even at room temperature (low temperature), the yellowing resistance of a cured product is low, making it difficult to apply in applications where transparency is required. Thus, there is still room for improvement in pressure-sensitive adhesive strength to the base material.

Note that in order to solve the aforementioned problems, the present applicants have proposed a curable hot-melt silicone composition containing a resin-linear structure-containing organopolysiloxane block copolymer having a (meth)acryl functional group and a radical polymerization initiator, in Patent Document 3. However, no compositions containing as a main agent a chain organopolysiloxane having an alkenyl group are disclosed in the same document.

### RELATED ART DOCUMENTS

### Patent Documents

Patent Document 1: WO 2015/194158 A1
Patent Document 2: WO 2017/068762 A1
Patent Document 3: JP 2021-131772 A (unpublished at the time of filing)

### SUMMARY OF THE INVENTION

### Problem to be Solved by the Invention

An object of the present invention is to provide: a hot-melt silicone composition that can be cured in a wide temperature range from low temperatures to high temperatures according to sealing and adhering processes and the heat resistance of a resin member, and particularly can achieve favorable curability under low temperatures such as room temperature and the like, enable design of adhesion and pressure-sensitive adhesive strength of a resulting cured product to a base material over a wide range, has excellent physical strength such as durability and the like, has excellent transparency, and has excellent handling workability of overmolding and the like; and a use thereof.

### Means for Solving the Problem

As a result of extensive studies, it was discovered that the aforementioned problem can be solved by a hot-melt curable organopolysiloxane composition containing (A) 1 to 50 parts by mass of a chain organopolysiloxane having two or more alkenyl groups in a molecule, (B) 50 to 99 parts by mass of an organopolysiloxane resin containing an M unit expressed by R₃SiO_{1/2} (where R mutually independently represents a monovalent organic group) and a siloxane unit (Q unit) expressed by SiO_{4/2} in a molecule, and in which the substance ratio of M units to 1 mol of Q units is in the range of 0.5 to 2.0, and (C) 0.1 to 10 parts by mass of a radical polymerization initiator, and optionally containing (D) 0 to 50 parts by mass of a radical reactive component of one to more selected from (D1) monofunctional or polyfunctional vinyl monomers, and (D2) organopolysiloxane compounds having an organic group having at least one of an acryl or methacryl group in a molecule, wherein the amount of component (B) is 50 mass % or more with respect to the total mass of the solid fraction of the composition, thereby arriving at the present invention.

In particular, when at least a portion of component (C) is a (C1) photoradical polymerization initiator, a hot-melt curable organopolysiloxane composition with favorable curability at room temperature can be achieved due to photocurability by irradiation with a high-energy beam.

Furthermore, the problem above can be suitably solved by the hot-melt curable organopolysiloxane composition above molded in sheet or film, a releasable laminate body containing the same, and a manufacturing method thereof. Similarly, the problem above is suitably solved by: a cured product obtained by curing the hot-melt curable organopolysiloxane composition according to the present invention; a semiconductor device or optical semiconductor device having the cured product; and a method of sealing or adhering the same.

### Effect of the Invention

The hot-melt curable organopolysiloxane composition of the present invention has favorable hot-melt properties, can be cured in a wide temperature range from room temperature and other low temperatures to high temperatures by high-temperature heat curing and/or irradiation with a high-energy beam of UV rays or the like according to sealing and adhering processes and the heat resistance of a resin member, and particularly can achieve favorable curability under low temperatures such as room temperature and the like, enables design of adhesion and pressure-sensitive adhesive strength of a resulting cured product to a base material over a wide range, has excellent physical strength such as durability and the like, has excellent transparency, and has excellent handling workability of overmolding and the like. Therefore, the composition can be suitably used in various sealing/adhering processes or as a substrate material, and particularly as a sealing agent for protecting a resin substrate with low heat resistance or an adhesive member of a substrate or the like, based on the selection of the curing system.

Furthermore, the present invention can provide such a hot-melt curable organopolysiloxane composition in the form of a sheet or film with a thickness of 10 to 1000 μm without a void or the like, or in the form of a releasable laminate body containing such a curable silicone composition sheet or film as well as a release sheet or film. In addition, a sheet or film containing the hot-melt curable organopolysiloxane composition of the present invention or a releasable laminate body containing the same can be cut to a desired size and used as needed in a manufacturing process or the like of an electronic component, such as a semiconductor device, can be applied to an industrial production process, such as batch sealing, batch adhering, or the like, to a large-area base material, and can achieve a favorable sealing process at room temperature and other low temperatures, by high-energy beam irradiation, particularly with the selection of a curing agent and curing system.

### DESCRIPTION OF THE PREFERRED EMBODIMENTS

Embodiments of the present invention will be described below in detail. The present invention is not limited by the following embodiments, and various types of modifications may be made within the scope of the gist of the present invention.

In the present specification, room temperature refers to the temperature of an environment in which a person handling the curable organopolysiloxane composition of the present invention is located. Room temperature typically refers to 0° C. to 40° C., particularly to 15 to 30° C., and more particularly to 18° C. to 25° C.

In the present invention, unless otherwise stated, “having hot-melt properties” means the softening point of a composition is 50 to 200° C. and the composition has flowable properties at high temperatures. In particular, the hot-melt curable organopolysiloxane composition of the present invention has a pre-cured complex viscosity at 25° C. exceeding 500 Pa·s or is a solid and thus has no fluidity. On the other hand, the complex viscosity of the pre-cured composition at 80° C. is preferably 20% or less of the complex viscosity at 25° C. (in other words, the rate of change of the complex viscosity from 25° C. to 80° C. is 80% or more). For practical purposes, the complex viscosity of the pre-cured composition at 80° C. is preferably 500,000 Pa·s or less. Moreover, the composition preferably has a melt viscosity in the range of 10 to 300,000 Pa·s. In particular, when the complex viscosity of the pre-cured composition at 80° C. is in the range above, low-temperature fluidity is excellent, which provides an advantage in which the present composition can be filled or molded into a site to be sealed at a relatively low temperature, even for a base material with low heat resistance.

In the present invention, the complex viscosity at a certain temperature refers to the complex viscosity recorded at a specific temperature by measuring the complex viscosity in the range of 25° C. to 100° C. at a temperature increase rate of 2° C./min using a complex viscometer such as MCR302 manufactured by Anton Paar or the like.

The hot-melt curable organopolysiloxane composition of the present invention contains components (A) to (C) above and may optionally contain radical reactive component (D). From the perspective of handling workability, the composition may optionally contain an organic solvent (F) as well as a photosensitizer or other additive within a scope not contrary to the object of the present invention. Hereinafter, each component will be described.

### [Component (A)]

Component (A) is a chain polysiloxane molecule with at least two alkenyl groups in a molecule, and is a main agent (base polymer) of this composition. Examples of the alkenyl groups of the organopolysiloxane of component (A) include vinyl groups, allyl groups, butenyl groups, pentenyl groups, hexenyl groups, heptenyl groups, and other alkenyl groups having 2 to 10 carbon atoms, with vinyl groups or hexenyl groups being particularly preferable. Examples of the bonding position of the alkenyl groups of component (A) include molecular chain ends and/or molecular side chains. From the perspective of the technical effect of the present invention, at least a portion or all of component (A) preferably has an alkenyl group bonded to a silicon atom at a site other than a molecular chain end, and the use of a chain organopolysiloxane having an alkenyl group on a molecular side chain is one preferred embodiment of the present invention. Note that component (A) may contain a single component or may be a mixture of two or more different components.

Examples of silicon atom-bonded organic groups other than alkenyl groups in the organopolysiloxane of component (A) include: methyl groups, ethyl groups, propyl groups, butyl groups, pentyl groups, hexyl groups, heptyl groups, and other alkyl groups; phenyl groups, tolyl groups, xylyl groups, naphthyl groups, and other aryl groups; benzyl groups, phenethyl groups, and other aralkyl groups; chloromethyl groups, 3-chloropropyl groups, 3,3,3-trifluoropropyl groups, and other alkyl halide groups; and the like, with methyl groups and phenyl groups being particularly preferable.

Component (A) is different from component (B) and has a chain polysiloxane molecular structure. For example, component (A) is preferably a linear or partially branched straight chain (branched) and may partially include a cyclic three-dimensional network. Preferably, the main chain contains repeating diorganosiloxane units and is preferably a linear or branched diorganopolysiloxane blocked at both molecular chain ends with triorganosiloxy groups. Note that the siloxane units which provide a branched organopolysiloxane are T units or Q units described later.

At room temperature, component (A) may have oil-like or raw rubber-like properties. However, particularly if the curable organopolysiloxane composition according to the present invention is a solvent-free or low-solvent composition, component (A) preferably has oil-like properties at room temperature from the perspective of coating properties. Component (A) preferably has a viscosity at 25° C. of 1 mPa·s or more and 100,000 mPa·s or less, and in view of the vinyl amount described later, the viscosity is particularly preferably 10 mPa·s or more, 50,000 mPa·s or less, and particularly 10,000 mPa·s or less. Note that when the curable organopolysiloxane composition according to the present invention is a solvent type, at least a portion of component (A) may be a raw rubber-like alkenyl group-containing organopolysiloxane having a viscosity exceeding 100,000 mPa·s at 25° C. or having a plasticity (thickness when a 1 kgf load applied for 3 minutes to a 4.2 g spherical sample at 25° C. is read up to 1/100 mm and this value is multiplied by 100) within the range of 50 to 200, and more preferably within the range of 80 to 180 as measured in accordance with the method as prescribed in JIS K6249.

The amount of alkenyl groups in component (A) is preferably in the range of 0.001 to 10 mass %, preferably in the range of 0.005 to 5.0 mass %, and more preferably in the range of 0.01 to 3.0 mass % with respect to the mass of component (A). In particular, it is preferable to use an organosiloxane in which the amount of the vinyl (CH₂═CH—) moiety in the aliphatic unsaturated carbon-carbon bond-containing group (hereinafter referred to as the “vinyl amount”) is in the range of 0.005 to 10.0 mass %, and particularly preferably in the range of 0.005 to 5.0 mass %.

Component (A) may include, as an organic group other than an aliphatic unsaturated carbon-carbon bond-containing group, a methyl group, an ethyl group, a propyl group, a butyl group, a pentyl group, a hexyl group, a heptyl group, or other alkyl group; a phenyl group, a tolyl group, a xylyl group, a naphthyl group, or other aryl group; a benzyl group, a phenethyl group, or other aralkyl group; a phenethyl group or other aralkyl group; and a chloromethyl group, a 3-chloropropyl group, a 3,3,3-trifluoropropyl group, or other alkyl halide group. From an industrial perspective, a methyl group is particularly preferably included. On the other hand, from the perspective of elongation of the cured product particularly at high temperature, adhesion to a base material, and transparency, and particularly reducing haze value, a methyl group is preferred as the organic group other than the aliphatic unsaturated carbon-carbon bond-containing group in component (A), and the amount of aryl groups or aralkyl groups is less than 0.1 mol % with respect to the total number of groups bonded to a silicon atom, and particularly 0.0 mol %. Thus, an aryl group or an aralkyl group is preferably essentially not included.

Such component (A) may be used alone or as a mixture of a plurality. However, from the perspective of the technical effects of the present invention, and particularly the elongation of a cured product and adhesion to a base material, component (A) may be one selected from:
(A1) a linear or branched organopolysiloxane having at least two alkenyl groups only at both molecular chain ends; and
(A2) a linear or branched organopolysiloxane having at least one alkenyl group at a site other than a molecular chain end and having at least three alkenyl groups in a molecule, or
component (A) may be a mixture containing both at an arbitrary mass ratio. Furthermore, these components (A1) and (A2) may and preferably are mixtures of two or more types of components with different viscosities, degrees of siloxane polymerization, or alkenyl group amounts.

Note that volatile or low molecular weight siloxane oligomers (octamethyltetrasiloxane (D4), decamethylpentasiloxane (D5), and the like) are preferably reduced or removed from component (A), from the perspective of preventing contact failure and the like. While the amount can be designed as desired, the amount may be less than 1 mass % of all of component (A), less than 0.1 mass % of siloxane oligomers, or may be reduced to a level near the detection limit, if necessary.

### [Component (B)]

Component (B) is an organopolysiloxane resin, and is a component in which the amount of component (B) in the total mass of the solid fraction of the composition is 50 mass % or more to achieve hot-melt properties of the composition as a whole and to adjust the adhesive strength, in other words, the adhesion strength to a base material, of a cured product obtained by curing the composition according to the present invention. In other words, the hardness of the cured product of the present composition and adhesion properties to a base material can be adjusted according to the amount of component (B) used. Specifically, if the amount of component (B) is small, the cured product tends to be flexible and has low adhesion properties to a base material surface, and can be easily removed from the base material surface by interfacial peeling during release between base materials. On the other hand, as the amount of component (B) increases, the adhesion properties of the cured product to the base material surface tends to increase. In particular, when more than 100 parts by mass of component (B) is used with respect to 100 parts by mass of component (A), as in the present invention, the pressure-sensitive adhesive layer forms a strong joint body with the base material surface and tends to become a permanent adhesive mode, with cohesive breakdown of the adhesive layer upon peeling.

Component (B) is an organopolysiloxane resin containing in a molecule a siloxane unit (M unit) expressed by R₃SiO_{1/2} (where R mutually independently represents a monovalent organic group) and a siloxane unit (Q unit) expressed by SiO_{4/2}. The molar ratio of M units to Q units is preferably 0.5 to 2.0. This is because when the molar ratio is less than 0.5, adhesion to the base material of the cured product may be reduced, whereas when the molar ratio is greater than 2.0, the cohesive strength of a material configuring a close-attachment layer decreases.

In particular, the molar ratio of M units to Q units is preferably within the range of M units:Q units=0.50:1.00 to 1.50:1.00, more preferably within the range of 0.55:1.00 to 1.20:1.00, and even more preferably within the range of 0.60:1.00 to 1.10:1.00. The molar ratio can be easily measured by ²⁹Si nuclear magnetic resonance.

Component (B) is preferably an organopolysiloxane resin expressed by general unit formula: (R₃SiO_{1/2})ₐ(SiO_{4/2})_{b} (where R mutually independently represents a monovalent organic group, a and b are positive numbers, respectively, and a+b=1 and a/b=0.5 to 1.5).

Component (B) may contain only M units and Q units, including the MVi units described above, but may also include an R₂SiO_{2/2} unit (D unit) and/or RSiO_{3/2} unit (T unit). Note that in the formula, R mutually independently represents a monovalent organic group. The total amount of M units and Q units in component (B) is preferably 50 wt. % or more, more preferably 80 wt. % or more, and particularly preferably 100 wt. %.

The monovalent organic group of R is preferably a monovalent hydrocarbon group having 1 to 10 carbon atoms, and examples thereof include alkyl groups having 1 to 10 carbon atoms, alkenyl groups having 2 to 10 carbon atoms, aryl groups having 6 to 10 carbon atoms, cycloalkyl groups having 6 to 10 carbon atoms, benzyl groups, phenylethyl groups, and phenylpropyl groups. In particular, 90 mol % or more of R is preferably alkyl groups having 1 to 6 carbon atoms or phenyl groups, while 95 to 100 mol % of R is particularly preferably methyl groups or phenyl groups. Furthermore, from the perspective of reducing the haze value of the cured product, a methyl group is suitable as a monovalent organic group in component (B), and the amount of aryl or aralkyl groups is preferably 0.1 mol % based on the total amount groups bonded to a silicon atom, but having substantially no aryl or aralkyl groups, or 0.0 mol %, is particularly preferable.

The weight average molecular weight (Mw) of the organopolysiloxane resin serving as component (B), as measured by gel permeation chromatography (GPC) in standard polystyrene equivalent, is preferably 2500 or more, more preferably 3000 or more, and particularly preferably 3500 or more. In practical use, component (B) is particularly preferably a resin containing the aforementioned R₃SiO_{1/2} unit (M unit) and SiO_{4/2} unit (Q unit), where the weight average molecular weight (Mw) is within the range of 2000 to 50,000. In particular, the use of a selective combination of a chain organopolysiloxane having the vinyl amount above and a high-molecular weight organopolysiloxane resin may result in a cured product with a relatively high shear storage elastic modulus at room temperature and tensile stress at 500% strain.

On the other hand, an organopolysiloxane resin in which low molecular weight and high molecular weight components (components that easily aggregate into a gel-like state, tend to increase haze values, and reduce low temperature curability) have been removed in advance can be used as component (B). Specifically, an organopolysiloxane pressure-sensitive adhesive layer with a low haze value in the cured product may be achievable by using an organopolysiloxane resin having a weight average molecular weight (Mw) in the range of 1,000 to 10,000, which, for example, is an organopolysiloxane resin in which the amount of the organopolysiloxane resin having a molecular weight of 100,000 or more is 1 mass % or less of the total amount, more preferably 0.5 mass % or less, and particularly preferably essentially 0 mass %.

### [Reduction of Hydroxyl Groups or Hydrolyzable Groups]

A hydroxyl group, alkoxy group, or other hydrolyzable group in component (B) is directly bonded to a silicon atom of a T unit, Q unit, or the like of the siloxane unit in a resin structure, and is a group derived from a raw material silane or group resulting from hydrolysis of the silane. Therefore, the amount of hydroxyl groups or hydrolyzable groups can be reduced by hydrolyzing a synthesized organopolysiloxane resin with a trimethylsilane or other silylating agent. This can suppress the formation of an organopolysiloxane resin structure with a large molecular weight in the cured product, can further improve the curability of the composition at low temperatures and the storage elastic modulus of the resulting cured product layer, and may improve favorable adhesion properties to a base material and removability from the surface of the base material after exposure to high temperatures.

In the present invention, component (B) is an organopolysiloxane resin expressed by the general unit formula: (R₃SiO_{1/2})ₐ(SiO_{4/2})_{b} (where R mutually independently represents a monovalent saturated organic group, a and b are each positive numbers, and a+b=1 and a/b=0.5 to 1.5). Moreover, 90 mol % or more of R is preferably alkyl groups having 1 to 6 carbon atoms or phenyl groups, 95 to 100 mol % of R is particularly preferably methyl groups or phenyl groups, and a resin (also called MQ resin) in which the amount of hydroxyl groups or hydrolyzable groups in component (B) is within the range of 0 to 7 mol % (0.0 to 1.50 mass % as hydroxyl groups) of all silicones is most preferably used.

Examples of such component (B) can include the following.

(Me₃SiO_{1/2})_{0.45}(SiO_{4/2})_{0.55}(HO_{1/2})_{0.05}

(Me₃SiO_{1/2})_{0.40}(SiO_{4/2})_{0.60}(HO_{1/2})_{0.10}

(Me₃SiO_{1/2})_{0.52}(SiO_{4/2})_{0.48}(HO_{1/2})_{0.01}

(Me₃SiO_{1/2})_{0.40}(Me₂ViSiO_{1/2})_{0.05}(SiO_{4/2})_{0.55}(HO_{1/2})_{0.05}

(Me₃SiO_{1/2})_{0.45}(SiO_{4/2})_{0.55}(MeO_{1/2})_{0.10}

(Me₃SiO_{1/2})_{0.25}(Me₂PhSiO_{1/2})_{0.20}(SiO_{4/2})_{0.55}(HO_{1/2})_{0.05}

(Me₃SiO_{1/2})_{0.40}(Me₂SiO_{2/2})_{0.05}(SiO_{4/2})_{0.55}(HO_{1/2})_{0.05}

(Me₃SiO_{1/2})_{0.40}(MeSiO_{3/2})_{0.05}(SiO_{4/2})_{0.55}(HO_{1/2})_{0.05}

(Me₃SiO_{1/2})_{0.40}(Me₂SiO_{2/2})_{0.05}(MeSiO_{3/2})_{0.05}(SiO_{4/2})_{0.50}(HO_{1/2})_{0.05}

(Me: methyl group, Ph: phenyl group, MeO: methoxy group, HO: silicon-atom bonded hydroxyl group.

Note that in order to express the relative amount of hydroxyl groups to silicon atoms, the total amount of the subscripts of units containing a silicon atom is set to 1, and the subscript of the (HO)_{1/2} unit indicates the relative amount).

Note that from the perspective of preventing contact failure, the low molecular weight siloxane oligomer in component (B) may be reduced or removed.

### [Amount of Component (B) and Mass % in Solid Fraction]

Component (B) is a component that achieves the hot-melt properties of the composition according to the present invention, adjusts the storage elastic modulus of a cured product, and imparts adhesion properties to a desired base material. Therefore, when the blending amount of component (A) in the composition is 1 to 50 parts by mass, the amount of component (B) is in the range of 50 to 99 parts by mass. When the blending amount is small, the pressure-sensitive adhesive layer has a relatively weak adhesion strength to the base material, and when the blending amount is large, the pressure-sensitive adhesive layer has a high adhesion strength to the base material and exhibits strong adhesive properties. Thereby the cured product according to the present invention has an advantage in which the adhesion properties and pressure-sensitive adhesive strength to a base material can be designed over a wide range.

Furthermore, from the perspective of hot-melt properties and handling workability of the composition, the amount of component (B) above in the total mass of the solid fraction of the composition (components that form a cured product, excluding organic solvents) must be 50 mass % or more, and is preferably in the range of 55 to 95 mass %. On the other hand, if the amount of component (B) is less than the lower limit above, even if component (D) or the like is used in place of component (B), the hot-melt properties of the resulting composition may decrease, and when the hot-melt composition is formed into a sheet/film or the like, the handling workability may be greatly impaired due to stickiness and reduced mold release properties on the surface of the composition. In addition, the ratio of the sum of the masses of components (A), (B), and (D2) to the total mass of the solid fraction of the present composition can be defined as the “siloxane mass % of the composition,” and the siloxane mass % is preferably 55 and 99.5 mass %. When the siloxane mass % is in the range of 60 to 99.5 mass %, the organopolysiloxane pressure-sensitive adhesive layer according to the present invention can be designed to have a transparent appearance, the flexibility of silicone, and sufficient adhesive strength to a base material.

### [Mass Ratio of Component (B) to Component (A) and Component (D2)]

The curable organopolysiloxane composition according to the present invention provides a cured product that can be designed for hot-melt properties as well as a wide range of adhesive properties and pressure-sensitive adhesive strength to a base material. Therefore, the mass ratio of the organopolysiloxane resin of component (B) to the sum of the chain reactive siloxane component of component (A) and component (D2) to be described later (=[mass of component (B)]/[sum of mass of component (A)+component (D2)]) must be greater than 1.0, and is preferably in the range of 1.1 to 5.0. When the organopolysiloxane resin above is selected as component (B) and the resin component above is blended with a chain siloxane polymer component to be in the range above, the composition as a whole exhibits favorable hot-melt properties. Moreover, viscoelastic properties such as high storage elastic modulus, stress, and the like at room temperature tend to be suitably realized in a cured product obtained by curing the composition.

### [Component (C)]

Component (C) is a radical polymerization initiator, may be (C1) a photoradical polymerization initiator, (C2) a thermal radical polymerization initiator, and a combination thereof, and the type of component (C), curing method, and curing temperature may be selected as appropriate based on the curing and adhering processes for the curable organopolysiloxane composition according to the present invention, heat resistance of the base material, demand for low energy consumption, and the like. The composition according to the present invention has an alkenyl group in component (A) serving as a main agent, and thus favorable curability can be achieved by irradiation with a high-energy beam and/or heating in the presence of component (C).

When the mass of component (A) is 1 to 50 parts by mass, the amount of component (C) used is 0.1 to 10 parts by mass, and particularly preferably 0.2 to 5 parts by mass. Note that the amount of component (C) to be used can be appropriately designed within the range above based on the forming process and curing time of the pressure-sensitive adhesive layer to which the present composition is applied, the amount of alkenyl groups derived from component (A), the high-energy beam irradiation dose, and/or the heating conditions.

Component (C1) is a photoradical polymerization initiator, and is a component that promotes the photocuring reaction of the alkenyl group in component (A), and optionally a thiol compound (E), through high-energy beam irradiation of UV rays and the like.

The photoradical polymerization initiators are known to be broadly classified into photo-fragmentation and hydrogen abstraction types. However, the photoradical polymerization initiator used in the composition of the present invention can be optionally selected from those known in the technical field, and is not limited to any particular one. Note that some photoradical polymerization initiators can promote curing reactions not only when irradiated with a high-energy beam of UV rays or the like, but also when irradiated with light in the visible light range.

Specific examples of the photoradical polymerization initiator include α-ketol compounds such as 4-(2-hydroxyethoxy)phenyl (2-hydroxy-2-propyl) ketone, α-hydroxy-α, α′-dimethylacetophenone, 2-methyl-2-hydroxypropiophenone, 1-hydroxycyclohexyl phenyl ketone, and the like; acetophenone compounds such as methoxyacetophenone, 2,2-dimethoxy-2-phenylacetophenone, 2,2-diethoxyacetophenone, 2-methyl-1-[4-(methylthio)-phenyl]-2-morpholinopropane-1, and the like; benzoin ether compounds such as benzoin ethyl ether, benzoin isopropyl ether, anisoin methyl ether, and the like; ketal compounds such as benzyl dimethyl ketal and the like; aromatic sulfonyl chloride compounds such as 2-naphthalenesulfonyl chloride and the like; photoactive oxime compounds such as 1-phenone-1,1-propanedione-2-(o-ethoxycarbonyl) oxime and the like; benzophenone compounds such as benzophenone, benzoylbenzoic acid, 3,3′-dimethyl-4-methoxybenzophenone, and the like; thioxanthone compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, 2,4-diisopropylthioxanthone, and the like; camphorquinone; halogenated ketones; and the like.

Similarly, examples of photoradical polymerization initiators suitable as component (C1) in the present invention can include: bisacylphosphine oxides such as bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propyl phenylphosphine oxide, bis(2,4,6-trimethylbenzoyl)-phenylphosphine oxide, bis(2,6-dimethoxybenzoyl)-2,4,4-trimethylpentylphosphine oxide, bis(2,6-dichlorbenzoyl)-4-propylphenylphosphine oxide, bis(2,6-dichlorobenzoyl)-2,5-dimethylphenylphosphine oxide, bis-(2,6-dimethoxybenzoyl)-2,5-dimethylphenylphosphine oxide, bis-(2,4,6-trimethylbenzoyl)-phenylphosphine oxide, and the like; monoacylphosphine oxides such as 2,6-dimethoxybenzoyldiphenylphosphine oxide, 2,6-dichlorobenzoyldiphenylphosphine oxide, 2,4,6-trimethylbenzoylphenylphosphine acid methyl ester, 2-methylbenzoyldiphenylphosphine oxide, pivaloylphenylphosphinic acid isopropyl ester, 2,4,6-trimethylbenzoyldiphenylphosphine oxide, and the like; anthraquinones such as anthraquinone, chloroanthraquinone, 2-methylanthraquinone, 2-ethylanthraquinone, 2-tert-butylanthraquinone, 1-chloroanthraquinone, 2-amylanthraquinone, 2-aminoanthraquinone, and the like; benzoic acid esters such as ethyl-4-dimethylaminobenzoate, 2-(dimethylamino)ethylbenzoate, p-dimethylbenzoic acid ethyl ester, and the like; titanocenes such as bis(η5-2,4-cyclopentadien-1-yl)-bis(2,6-difluoro-3-(1H-pyrrol-1-yl)phenyl) titanium, bis(cyclopentadienyl)-bis [2,6-difluoro-3-(2-(1-pyl-1-yl)ethyl)phenyl]titanium, and the like; phenyl disulfide 2-nitrofluorene; butyroin; anisoin ethyl ether; azobisisobutyronitrile; tetramethylthiuram disulfide; and the like.

Examples of commercially available acetophenone photopolymerization initiators suitable as component (C1) in the present invention include Omnirad 907, 369, 369E, and 379 manufactured by IGM Resins, Inc., and the like. Furthermore, examples of commercially available acylphosphine oxide photopolymerization initiators include Omnirad TPO, TPO-L, and 819 manufactured by IGM Resins, Inc., and the like. Examples of commercially available oxime ester photopolymerization initiators include Irgacure OXE01 and OXE02 manufactured by BASF Japan Co., Ltd., N-1919, Adeka ARKLS NCI-831, and NCI-831E manufactured by ADEKA Co., Ltd., TR-PBG-304 manufactured by Changzhou Tronly New Electronics Materials Co., Ltd., and the like.

Component (C2) is a thermal radical polymerization initiator that generates radical species by heating and promotes photocuring reactions of alkenyl groups in components (A) and (D), and optionally thiol compound (E). Examples of such thermal radical polymerization initiators include azo compounds, organic peroxides, and the like.

Examples of azo compounds include 2,2′-azobisisobutyronitrile, 2,2′-azobis(2-methylbutyronitrile), 2,2′-azobis(2,4-dimethylvaleronitrile), 1,1′-azobis-1-cyclohexanecarbonitrile, dimethyl-2,2′-azobisisobutyrate, dimethyl-2,2′-azobis(2-methylpropionate), dimethyl-1,1′-azobis(1-cyclohexanecarboxylate), 4,4′-azobis(4-cyanovaleric acid), 2,2′-azobis(2-amidinopropane) dihydrochloride, 2-tert-butylazo-2-cyanopropane, 2,2′-azobis(2-methylpropionamide) dihydrate, 2,2′-azobis(2,4,4-trimethylpentane), and the like.

Examples of organic peroxides include alkyl peroxides, diacyl peroxides, ester peroxides, and carbonate peroxides. Specific examples of alkyl peroxides include dicumyl peroxide, di-tert-butyl peroxide, di-tert-butylcumyl peroxide, 2,5-dimethyl-2,5-di(tert-butylperoxy) hexane, 2,5-dimethyl-2,5-di(tert-butylperoxy) hexyne-3, tert-butylcumyl, 1,3-bis(tert-butylperoxyisopropyl)benzene, and 3,6,9-triethyl-3,6,9-trimethyl-1,4,7-triperoxonan. Examples of diacyl peroxides include benzoyl peroxide, lauroyl peroxide, and decanoyl peroxide. Examples of ester peroxides include 1,1,3,3-tetramethylbutylperoxyneodecanoate, α-cumylperoxyneodecanoate, tert-butylperoxyneodecanoate, tert-butylperoxyneoheptanoate, tert-butylperoxypivalate, tert-hexylperoxypivalate, 1,1,3,3-tetramethylbutylperoxy-2-ethylhexanoate, tert-amylperoxyl-2-ethylhexanoate, tert-butylperoxy-2-ethylhexanoate, tert-butylperoxyisobutyrate, di-tert-tert-amylperoxy-3,5,5-trimethylhexanoate, tert-butylperoxyhexahydroterephthalate, butylperoxy-3,5,5-trimethylhexanoate, tert-butylperoxyacetate, tert-butylperoxybenzoate, and di-butylperoxytrimethyladipate. Examples of carbonate peroxides include di-3-methoxybutyl peroxydicarbonate, di(2-ethylhexyl) peroxydicarbonate, diisopropyl peroxycarbonate, tert-butyl peroxyisopropylcarbonate, di(4-tert-butylcyclohexyl) peroxydicarbonate, dicetyl peroxydicarbonate, and dimyristyl peroxydicarbonate.

### [Component (C′): Photosensitizer]

In the present composition, a photosensitizer (C′) may be used in combination with an optionally selected photoradical polymerization initiator (C1). Use of a sensitizer can increase the photon efficiency of the polymerization reaction, and is particularly effective when the coating thickness of the composition is relatively thick or when a relatively long-wavelength LED light source is used, because use of longer wavelength light for the polymerization reaction compared to only using a photoinitiator is feasible. Examples of known sensitizers include anthracene-based compounds, phenothiazine-based compounds, perylene-based compounds, cyanine-based compounds, melocyanine-based compounds, coumarin-based compounds, benzylidene ketone-based compounds, and (thio) xanthene- or (thio) xanthone-based compounds such as isopropylthioxanthone, 2,4-diethylthioxanthone, squarylium-based compounds, (thia) pyrylium-based compounds, porphyrin-based compounds, and the like. Moreover, an arbitrary photosensitizer not limited thereto can be used in the curable organopolysiloxane composition and pressure-sensitive adhesive composition of the present invention. The amount used is arbitrary, but is commonly selected within a range where the mass ratio of component (C′) to component (C1) is 0 to 10, and if present, is within the range of 0.01 to 5.

### [Selection of Component (C) and Curing Method]

Because the present composition includes the aforementioned component (A) and optionally component (E) to be described later, a cured product is formed by a radical polymerization reaction. Herein, when at least a part of component (C) is the photoradical polymerization initiator (C1), the present composition can be cured by high-energy beam irradiation of UV rays or the like. Similarly, when at least a part of component (C) is the thermal radical polymerization initiator (C2), the present composition can be cured by heating. Furthermore, combining the two makes it possible to select or combine heating and high-energy beam irradiation for curing, and the appropriate selection can be made according to the desired curing method and sealing/adhering processes.

In particular, with respect to the composition according to the present invention, at least a part of component (C) is the photoradical polymerization initiator (C1), and optionally further (C′) a photosensitizer, and therefore, environmental impact is low and a rapid curing reaction can be performed even at low temperatures including room temperature, even for base materials and members with inferior heat resistance, which thus provides an advantage in which the component can be suitably used in industrial production processes for reducing energy consumption in fields of semiconductors and the like. On the other hand, when at least a part of the component (C) is the thermal radical polymerization initiator (C2), this provides an advantage in which rapid curing is possible in a short time at high temperatures.

### [Component (D)]

The composition according to the present invention may optionally further include one or more radical reactive component selected from (D1) monofunctional or polyfunctional vinyl monomers and (D2) an organopolysiloxane compound having an organic group containing at least one of an acryl or methacryl group in a molecule. Note that the term “(meth)acrylic acid” as used below indicates that both acrylic acid and methacrylic acid are included. Similarly, “(meth)acrylate”, “(meth)acryloxy”, and “(meth)acrylamide” also indicate that both acrylate and methacrylate, acryloxy and methacryloxy, and acrylamide and methacrylamide, respectively, are included.

Similar to component (A), component (D) is a radical reactive component because a carbon-carbon unsaturated double bond derived mainly from an acryl or methacryl group is included in a molecule, and participates in a curing reaction through radical polymerization, similar to component (A). Therefore, when component (D) is optionally used, it is possible to; adjust the melt viscosity, adhesion strength to a base material, cross-linking density of a cured product, and the like; and depending on the amount of the composition used, to adjust the hardness and adhesion properties of the cured product obtained by curing or semi-curing the present composition to the base material. Thus, component (D) is particularly useful in adjusting the cross-linking density, and adjusting the pressure-sensitive adhesive strength with respect to the base material.

Use of the radical reactive component serving as component (D) is arbitrary, and the amount used is not particularly limited, but is preferably in the range of 0.1 to 50 parts by mass and particularly preferably in the range of 0.1 to 25 parts by mass, with respect to 1 to 50 parts by mass of component (A).

Component (D1) is a vinyl monomer, which is a starting material for an organic resin generally referred to as a vinyl resin. Examples thereof include: methyl (meth)acrylate, ethyl (meth)acrylate, n-propyl (meth)acrylate, isopropyl (meth)acrylate, and other lower alkyl (meth)acrylates; glycidyl (meth)acrylates; n-butyl (meth)acrylate, isobutyl (meth)acrylate, tert-butyl (meth)acrylate, n-hexyl (meth)acrylate, cyclohexyl (meth)acrylate, 2-ethylhexyl (meth)acrylate, isoamyl (meth)acrylate, octyl (meth)acrylate, dodecyl (meth)acrylate, isobornyl (meth)acrylate, stearyl (meth)acrylate, dicyclopentanyl (meth)acrylate, dicyclopentenyl (meth)acrylate, 3,3,5-tricyclohexyl (meth)acrylate, phenoxyethyl (meth)acrylate, and other higher (meth)acrylates; vinyl acetate, vinyl propionate, and other lower fatty acid vinyl esters; vinyl butyrate, vinyl caproate, vinyl 2-ethylhexanoate, vinyl laurate, vinyl stearate, and other higher fatty acid esters; styrene, vinyl toluene, benzyl (meth)acrylate, phenoxyethyl (meth)acrylate, vinyl pyrrolidone, and other aromatic vinyl monomers; (meth)acrylamide, N-methylol (meth)acrylamide, N-methoxymethyl (meth)acrylamide, isobutoxymethoxy (meth)acrylamide, N,N-dimethyl (meth)acrylamide, and other amide group-containing vinyl monomers; 2-hydroxyethyl (meth)acrylate, 4-hydroxybutyl (meth)acrylate, 2-hydroxybutyl (meth)acrylate, 2-hydroxypropyl (meth)acrylate, tetrahydrofurfuryl (meth)acrylate, and other hydroxyl group-containing vinyl monomers; trifluoropropyl (meth)acrylate, perfluorobutylethyl (meth)acrylate, perfluorooctylethyl (meth)acrylate, and other fluorine-containing vinyl monomers; glycidyl (meth)acrylate, 3,4 epoxycyclohexylmethyl (meth)acrylate, and other epoxy group-containing vinyl monomers; (meth)acrylic acid, itaconic acid, crotonic acid, fumaric acid, maleic acid, and other carboxylic acid-containing vinyl monomers; tetrahydrofurfuryl (meth)acrylate, butoxyethyl (meth)acrylate, ethoxydiethylene glycol (meth)acrylate, polyethylene glycol (meth)acrylate, polypropylene glycol mono(meth)acrylate, hydroxybutyl vinyl ether, cetyl vinyl ether, 2-ethylhexyl vinyl ether, diethylene glycol monoethyl ether (meth)acrylate, diethylene glycol monomethyl ether (meth)acrylate, and other ether bond-containing vinyl monomers; (meth)acryloxy propyltrimethoxysilane, polydimethylsiloxane containing a styryl group at one end, and other unsaturated group-containing silicone compounds; butadiene; vinyl chloride; vinylidene chloride; (meth)acrylonitrile; dibutyl fumarate; maleic anhydride; dodecyl succinic anhydride; (meth)acryl glycidyl ether; alkali metal salt, ammonium salt, or organic amine salt of a radically polymerizable unsaturated carboxylic acid such as (meth)acrylic acid, itaconic acid, crotonic acid, fumaric acid, maleic acid, or the like; radically polymerizable unsaturated monomers having a sulfonic acid group such as styrene sulfonic acid, as well as alkali metal salts thereof, ammonium salts thereof, and organic amine salts thereof; and quaternary ammonium salts derived from (meth)acrylic acid, such as 2-hydroxy-3-methacryloxy propyltrimethylammonium chloride, methacrylate esters of alcohols having a tertiary amine group, such as a diethylamine methacrylate ester, and quaternary ammonium salts thereof.

Similarly, a polyfunctional vinyl monomer can also be used. Examples thereof include: diethylene glycol di(meth)acrylate, triethylene glycol di(meth)acrylate, tetraethylene glycol di(meth)acrylate, neopentyl glycol di(meth)acrylate, polyethylene glycol di(meth)acrylate, 1,4-bis((meth)acryloyloxy) butane, 1,6-bis((meth)acryloyloxy) hexane, 1,9-bis((meth)acryloyloxy) nonane, 1,10-bis((meth)acryloyloxy) decane, 1,12-bis((meth)acryloyloxy) dodecane, tris(2-acryloyloxy)ethyl isosialate, trimethylolpropane tri(meth)acrylate, pentaerythritol tri(meth)acrylate, neopentyl glycol di(meth)acrylate, trimethylolpropane trioxyethyl(meth)acrylate, tris(2-hydroxyethyl) isocyanurate di(meth)acrylate, tris(2-hydroxyethyl) isocyanurate tri(meth)acrylate, adduct diol di(meth)acrylate of bisphenol A ethylene oxide or propylene oxizide, ethylene oxide of hydrogenated bisphenol A or propylene oxide adduct diol di(meth)acrylate, triethylene glycol divinyl ether, and other (meth)acryloyl group-containing monomers; polydimethylsiloxane blocked with styryl groups on both ends and other silicone compounds containing an unsaturated group; and the like.

In the present invention, a preferred component (D1) is a monofunctional or polyfunctional vinyl monomer having 8 or more carbon atoms, preferably 8 to 30 carbon atoms, and more preferably 13 to 30 carbon atoms. Such vinyl monomers have low volatility and relatively low viscosity, and thus tend to provide excellent workability and moldability in uncured compositions and a high glass transition temperature in the resulting cured product.

More specifically, a preferred component (D1) is an acrylate vinyl monomer having 8 or more carbon atoms, preferably 8 to 30 carbon atoms, and more preferably having 13 to 30 carbon atoms and having one acryloxy group, and can be used alone or in combination with two or more components, taking into consideration the viscosity, curability, hardness after curing, and glass transition temperature of the compound. Of these, vinyl monomers are preferably selected from dodecyl acrylate, 2-ethylhexyl acrylate, isobornyl acrylate, and dicyclopentanyl acrylate.

Similarly, a preferred component (D1) is an acrylate vinyl monomer having 8 or more carbon atoms, preferably 8 to 30 carbon atoms, and more preferably having 13 to 30 carbon atoms and having two or more acryloxy groups, and can be used alone or in combination with two or more components, taking into consideration the viscosity of the mixture, curability, compatibility with the aforementioned compound having one acryloxy group, hardness after curing and glass transition temperature of the compound. Diethylene glycol di(meth)acrylate, triethylene glycol di(meth)acrylate, 1,6-bis((meth)acryloyloxy) hexane, 1,12-bis((meth)acryloyloxy) dodecane, and trimethylolpropane tri(meth)acrylate, both-end acryloxy-functionalized polydimethylsiloxane can be preferably used. Furthermore, a compound not having a silicon atom, such diethylene glycol di(meth)acrylate, triethylene glycol di(meth)acrylate, 1,6-bis((meth)acryloyloxy) hexane, 1,12-bis((meth)acryloyloxy) dodecane, trimethylolpropane tri(meth)acrylate, and polyethylene glycol di(meth)acrylate (average degree of polymerization within the range of 4 to 30), is more preferably used.

Furthermore, in consideration of the aforementioned properties, these compounds having two or more acryloxy groups can be used in combination with the compounds having one acryloxy group. In this case, the two can be combined at an arbitrary ratio.

Furthermore, of the (meth)acrylates listed above, the haze resistance properties of the resulting cured product can be improved by using a (meth)acrylate compound (e.g., one or more selected from diethylene glycol di(meth)acrylates, triethylene glycol di(meth)acrylates, and trimethylolpropane tri(meth)acrylates, polyethylene glycol di(meth)acrylates) containing one or more ether bonds (—C—O—C—) in a molecule, alone or in combination. The preferred amount of the (meth)acrylate compound containing one or more ether bonds (—C—O—C—) in a molecule in the composition is 0.001 to 5 mass %, and more preferably suitably 0.05 to 2 mass %. The haze resistance properties herein refer to the property where the haze value of the material is 1 or lower even after exposure to a high humidity environment, or where if the haze value is 1 or higher, the haze value drops to 1 or lower under dry conditions.

Component (D2) is an organopolysiloxane compound having an organic group containing at least one acryl or methacryl group in a molecule, and any resin-like, chain-like (including linear and branched), cyclic, or resin-linear block copolymers including a resinous block and a chain block can be used thereas.

Component (D2) is preferably a chain organopolysiloxane having at least one silicon atom-bonded functional group R^{A}
expressed by general formula (1)

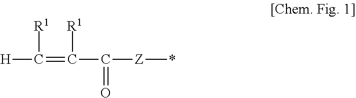

the silicon atom-bonded functional group being at an end or side chain of a molecular chain, where R¹ mutually independently represents a hydrogen atom, methyl group, or phenyl group, and is preferably a hydrogen atom or a methyl group in order to form an acryl or methacryl group portion. Z represents a divalent organic group which may contain a hetero atom and is bonded to a silicon atom configuring the main chain of the polysiloxane represented by *, and may be a divalent organic group which may contain a silicon, oxygen, nitrogen, or sulfur atom.

Herein, Z preferably represents one group selected from:
alkylene groups having 2 to 22 carbon atoms;
divalent organic groups expressed by

—R³—C(═O)—O—R⁴—
{where R³ represents an alkylene group having 2 to 22 carbon atoms, and R⁴ represents a group selected from ethylene groups, propylene groups, methylethylene groups and hexylene groups};
divalent organic groups expressed by

—Z¹—X—C(═O)—X—Z²—
{where Z¹ represents —O(CH₂)ₖ— (where k is a number in a range of 0 to 3), and X represents an oxygen atom, a nitrogen atom, or a sulfur atom, Z² represents a divalent organic group expressed by —[(CH₂₂O]ₘ(CₙH₂ₙ)— (where m is a number in the range of 0 to 3, and n is a number in the range of 2 to 10) bonded to a silicon atom configuring the main chain of the polysiloxane represented by *}; and
divalent linking groups expressed by
—Z¹—R²₂Si—O—R²₂Si—Z²— described later.

Particularly preferably, the silicon atom-bonded functional group (R^{A}) is expressed by general formula (1):

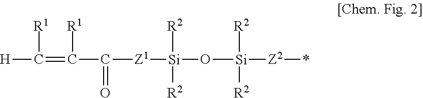

In the formula, R¹ mutually independently represents a hydrogen atom, a methyl group, or a phenyl group, and preferably a hydrogen atom or a methyl group. R² mutually independently represents an alkyl group or an aryl group, preferably an alkyl group or a phenyl group having 1 to 20 carbon atoms for industrial purposes, and particularly preferably a methyl group. Z¹ represents —O(CH₂)ₘ— (m is a number in the range 0 to 3), where m is preferably 1 or 2. Z² represents a divalent organic group expressed by —CₙH₂ₙ— (n is a number in a range of 2 to 10) bonded to a silicon atom configuring the main chain of the polysiloxane represented by *, and a case where n is 2 to 6 is preferred for practical use. Note that the silicon atom-bonded functional group (R^{A}) expressed by general formula (1-1) can be introduced into a molecule by reacting a silicon atom-bonded functional group containing at least one alkenyl group (R^{AlK}) and a hydrosilane compound having a silicon atom-bonded hydrogen atom and (meth)acryl functional group in a molecule (e.g., 3-(1,1,3,3-tetramethyldisiloxanyl) propyl methacrylate and the like), in the presence of a hydrosilylation reaction catalyst. Furthermore, the same reaction may be and preferably is performed in the presence of a polymerization inhibitor such as dibutylhydroxytoluene (BHT).

More specifically, component (D2) may include one or more types of chain organopolysiloxanes selected from components (D2-1-1) and (D2-1-2) described below.

Component (D2-1-1) is a linear organopolysiloxane having at least one functional group (R^{A}) in a molecule, as shown by the following structural formula.

Structural formula:

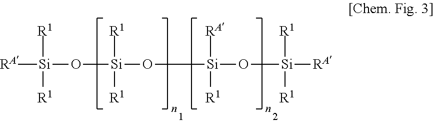

In the formula, R¹ mutually independently represents a C1 to C6 alkyl group, a C2 to C20 alkenyl group, or a C6 to C12 aryl group, R^{A′} mutually independently represents a group selected from C1 to C6 alkyl groups, C2 to C20 alkenyl groups, C6 to C12 aryl groups, and silicon atom-bonded functional groups (R^{A}) containing the aforementioned acryl or methacryl group, n1 is a positive number, and n2 is 0 or a positive number. However, when n2 is 0, at least one out of R^{A′} is a silicon atom-bonded functional group (R^{A}) containing the aforementioned acryl or methacryl group. n1+n2 is a positive number greater than or equal to 0 and is not limited, but is preferably in the range of 10 to 5000, more preferably 10 to 2000, and even more preferably 10 to 1000. Note that the value of n1+n2 may be and preferably is a number that satisfies a viscosity range such that the viscosity of component (C′1) at 25° C. is within the range of 1 to 100,000 mPa·s, more preferably 10 to 50,000 mPa·s, and even more preferably 500 to 50,000 mPa·s.

Component (D2-1-2) is a branched organopolysiloxane that has at least one functional group (R^{A}) in a molecule and includes a branched siloxane unit, as shown by the average unit formula below.

Average unit formula:

(R^{A′}R¹₂SiO_{1/2})ₓ(R¹₂SiO_{2/2})_{y1}(R^{A′}R¹SiO_{2/2})_{y2}(R¹SiO_{3/2})_{z1}(R^{A′}SiO_{3/2})_{z2} (I-2)

In the formula, R¹ and R^{A′} represent the same groups as described above, and x, y1, y2, z1 and z2 represent the molar ratio when the sum of each siloxane unit is 1. Specifically, if all of the following conditions are satisfied: x+y1+y2+z1+z2=1, 0<x≤0.2, 0.3≤y1+y2<1, 0<z1+z2≤0.2, y2+z2=0, at least one R^{A′} is the silicon atom-bonded functional group (RA) that includes the acryl or methacryl group described above. Note that either one or both y2 and z2 may be 0.

More specifically, the component (D2-1-2) is a branched organopolysiloxane expressed by the following siloxane unit formula.

(R^{A′}R¹₂SiO_{1/2})ₐ(R¹₂SiO_{2/2})_{b1}(R^{A′}R¹SiO_{2/2})_{b2}(R¹SiO_{3/2})_{c1}(R^{A′}SiO_{3/2})_{c2}

(where R¹ and R^{A′} represent the same groups as above)
When expressed by the formula above, 0<a≤10, 15≤b1+b2<2000, and 0<c1+c2≤10, and in the case of b2+c2=0, at least one of R^{A′} is a silicon atom-bonded functional group (R^{A}) that includes the acryl or methacryl group described above.

As an example, component (D2-1-2) may be a branched organopolysiloxane having a methacryloyl group-containing organic group only on an end M unit expressed by the siloxane unit formula below.

(R^{A′}R¹₂SiO_{1/2})ₐ(R¹₂SiO_{2/2})_{b1}(R¹SiO_{3/2})_{c1}

In the formula, R¹ and R^{A′} represent the same groups as above, 0<a≤10, 15≤b1<2000, 0<c1≤10, and at least one of R^{A′} is a silicon atom-bonded functional group (R^{A}) that includes the acryl or methacryl group described above.

The viscosity of component (D2-1-2) at 25° C. is preferably 10 to 50,000 mPa·s, and more preferably 100 to 2,000 mPa·s.

Examples of component (D2) widely available on the market include branched or linear polydimethylsiloxanes that include a (meth)acryl group at one end, polydimethylsiloxanes blocked at both ends with methacryloxypropyl, and the like.

### [Component (B-2)]

The composition according to the present invention contains an organopolysiloxane resin as component (B) above, and (B-2) an organopolysiloxane resin containing M units and Q units expressed by R^{B}₃SiO_{1/2} and R^{A}ₐR^{B}₍₃₋ₐ₎SiO_{1/2} in a molecule may be included as a portion of component (B) at a molar ratio of M units to Q units in the range of 0.5 to 2.0. In the formula, a represents an integer between 1 to 3, R^{A} represents a silicon atom-bonded functional group containing an acryl or methacryl group, and R^{B} represents a monovalent organic group excluding R^{A}, and may include: methyl groups, ethyl groups, propyl groups, butyl groups, pentyl groups, hexyl groups, heptyl group, and other alkyl groups; phenyl groups, tolyl groups, xylyl groups, naphthyl groups, and other aryl groups; benzyl groups, phenethyl group, and other aralkyl groups; chloromethyl groups, 3-chloropropyl groups, 3,3,3-trifluoropropyl groups, and other alkyl halide groups; and vinyl groups, allyl groups, butenyl groups, pentenyl groups, hexenyl groups, and other alkenyl groups. From an industrial perspective, it is particularly preferable to include one or more of the following groups: methyl groups, phenyl groups, vinyl groups, and hexenyl groups. Furthermore, at least a part of R^{B} may be and preferably is an alkenyl group having 2 to 12 carbon atoms. Furthermore, at least one of the M units configuring component (B-2) is a triorganosiloxy unit containing a functional group R_{A}, expressed by R^{A}ₐR^{B}₍₃₋ₐ₎SiO_{1/2}.

Component (B-2) is an MQ-type organopolysiloxane resin having an acryl or methacryl group in a molecule, and has a silicon atom-bonded functional group containing at least one acryl or methacryl group represented by R^{A} in a molecule, and thus is involved in the same curing reaction as component (A) and component (D). Component (B-2) is an optional component that adjusts the adhesion strength to a base material, the cross-linking density of a cured product, and the melt viscosity, and depending on the amount of the component used, it is possible to adjust the hardness of the cured product of the present composition and the adhesion properties thereof to a base material.

Component (B-2) may contain a small amount of siloxane units (T units) expressed by RSiO_{3/2} (R represents a monovalent organic group that may contain the aforementioned R^{A}) or siloxane units (D units) expressed by R²SiO_{2/2} (R represents the same monovalent organic group as above), but preferably substantially contains only the M units expressed by R^{B}₃SiO_{1/2} and R^{A}ₐR^{B}₍₃₋ₐ₎SiO_{1/2} and the Q units. The sum of the molar amounts of the T units and D units to 1 mol of Q units in component (C) is preferably less than 0.1 mol.

The ratio of the amount (molar ratio) of M units to Q units in component (B-2) is in the range of 0.5 to 2.0, preferably 0.5 to 1.5, more preferably 0.55 to 1.20, and particularly preferably 0.60 to 1.10.

The amount of component (B-2) is arbitrary and may be blended in the form of replacing a part of component (B) above. For example, component (B-2) may be used in the range of 0 to 50 mass % of the total amount of component (B), or may be 0 to 25 mass %.

### [(E) Thiol Compound]

The composition according to the present invention may further contain (E) a polyfunctional thiol compound having at least two or more thiol groups (—SH) in a molecule. The polyfunctional thiol compound acts as a chain transfer agent to promote a radical polymerization reaction, and thus is able to improve the curing rate and deep curability of a cured product, and function as a cross-linking point in the present composition, particularly when a part of component (C) according to the present invention is a photoradical polymerization initiator and the present composition is cured by high-energy beam irradiation of UV rays or the like, even when the irradiation dose of the high-energy beam is low.

Examples of the polyfunctional thiol compound include pentaerythritol tetrakis(3-mercaptobutyrate), 1,4-bis(3-mercaptobutyryloxy) butane, 1,3,5-tris(2-(3-sulfanylbutanoyloxy)ethyl)-1,3,5 triazinane-2,4,6-trione, trimethylolpropane tris(3-mercaptobutyrate), and the like.

Furthermore, component (E) may be an organopolysiloxane compound having an organic group containing at least two thiol groups in a molecule, and any resin-like, chain-like (including linear and branched), cyclic, or resin-linear block copolymers including a resinous block and a chain block can be used thereas. In the thiol group-containing organopolysiloxane compound serving as component (E), the bonding site of the thiol-modifying group is not particularly limited, and thus may be either at a molecular chain end or side chain. An example thereof is a linear organopolysiloxane with a thiol-modifying group at a side chain site, such as a dimethylsiloxane/2-thiolpropylmethylsiloxane copolymer blocked at a molecular chain end thereof with a trimethylsiloxy group, and the like. In particular, when component (E) is a thiol group-containing organopolysiloxane compound, compatibility with other structural components and the uniformity and viscosity of the entire composition can be improved, and in some cases, the cross-linking density within molecules can be adjusted.

The use of component (E) is optional, the amount thereof is 0 to 20 parts by mass relative to 1 to 50 parts by mass of component (A), preferably 0 to 10 parts by mass, and particularly preferably 0 to 5 parts by mass.

### [(F) Adhesion Imparting Agent]

The present composition may further contain a known adhesion imparting agent as component (F). Component (G) improves the adhesive strength of the cured product obtained by curing the present composition to a base material, and one or more types of known adhesion imparting agents can be selected for use. In particular, the use of a compound having two or more alkoxysilyl groups in a molecule as at least part of component (F) may greatly improve adhesive strength after a certain time.

The amount of component (F) used is 0.01 to 5 parts by mass when the entire composition according to the present invention is 100 parts by mass, and an amount of 0.02 to 2 parts by mass is particularly preferred. If the amount of component (F) used is less than the lower limit above, the adhesive force to the base material may not be sufficiently improved. If the amount exceeds the upper limit above, the compatibility with other components may deteriorate and the appearance of the cured product may be affected over time.

Component (F) preferably contains an organic compound having two or three alkoxysilyl groups at a molecular chain end. Furthermore, the organic compound herein include organic silicon compounds in addition to alkane compounds and the like.

Specific examples of organic compounds having two alkoxysilyl groups on a molecular chain end include 1,2-bis(trimethoxysilyl) ethane, 1,2-bis(triethoxysilyl) ethane, 1,2-bis(methyldimethoxysilyl) ethane, 1,2-bis(methyldiethoxysilyl) ethane, 1,3-bis(trimethoxysilyl) propane, 1,4-bis(trimethoxysilyl) butane, 1,4-bis(triethoxysilyl) butane, 1-methyldimethoxysilyl-4-trimethoxysilylbutane, 1-methyldiethoxysilyl-4-triethoxysilylbutane, 1,4-bis(methyldimethoxysilyl) butane, 1,4-bis(methyldiethoxysilyl) butane, 1,5-bis(trimethoxysilyl) pentane, 1,5-bis(triethoxysilyl) pentane, 1,4-bis(trimethoxysilyl) pentane, 1,4-bis(triethoxysilyl) pentane, 1-methyldimethoxysilyl-5-trimethoxysilylpentane, 1-methyldiethoxysilyl-5-triethoxysilylpentane, 1,5-bis(methyldimethoxysilyl) pentane, 1,5-bis(methyldiethoxysilyl) pentane, 1,6-bis(trimethoxysilyl) hexane, 1,6-bis(triethoxysilyl) hexane, 1,4-bis(trimethoxysilyl) hexane, 1,5-bis(trimethoxysilyl) hexane, 2,5-bis(trimethoxysilyl) hexane, 1-methyldimethoxysilyl-6-trimethoxysilylhexane, 1-phenyldiethoxysilyl-6-triethoxysilylhexane, 1,6-bis(methyldimethoxysilyl) hexane, 1,7-bis(trimethoxysilyl) heptane, 2,5-bis(trimethoxysilyl) heptane, 2,6-bis(trimethoxysilyl) heptane, 1,8-bis(trimethoxysilyl) octane, 1,8-bis(methyldimethoxysilyl) octane, 2,5-bis(trimethoxysilyl) octane, 2,7-bis(trimethoxysilyl) octane, 1,9-bis(trimethoxysilyl) nonane, 2,7-bis(trimethoxysilyl) nonane, 1,10-bis(trimethoxysilyl) decane, 3,8-bis(trimethoxysilyl) decane, and other alkane compounds having two alkoxysilyl groups, 1,3-bis{2-(trimethoxysilyl) ethyl}-1,1,3,3-tetramethyldisiloxane, 1,3-bis{2-(methyldimethoxysilyl) ethyl}-1,1,3,3-tetramethyldisiloxane, 1,3-bis{2-(triethoxysilyl) ethyl}-1,1,3,3-tetramethyldisiloxane, 1,3-bis{2-(methyldiethoxysilyl) ethyl}-1,1,3,3-tetramethyldisiloxane, 1,3-bis{6-(trimethoxysilyl) hexyl}-1,1,3,3-tetramethyldisiloxane, 1,3-bis{6-(triethoxysilyl) hexyl}-1,1,3,3-tetramethyldisiloxane, and other disiloxane compounds having two alkoxysilyl groups.

Similarly, examples of organic compounds having three alkoxysilyl groups include 1,3,5-tris{2-(trimethoxysilyl) ethyl}-1,1,3,5,5-pentamethyl trisiloxane, 1,3,5-tris{2-(methyldimethoxysilyl) ethyl}-1,1,3,5,5-tetramethyldisiloxane, 1,3,5-tris{2-(triethoxysilyl) ethyl}-1,1,3,5,5-tetramethyldisiloxane, 1,3,5-tris{2-(methyldiethoxysilyl) ethyl}-1,1,3,5,5-tetramethyl disiloxane, 1,3,5-tris{6-(trimethoxysilyl) hexyl}-1,1,3,5,5-tetramethyl disiloxane, and other trisiloxane compounds having three alkoxysilyl groups. An example of the structure is:

(MeO)₃SiCH₂CH₂(Me)₂Si—O—SiMe(CH₂CH₂Si(OMe)₃)—O—Si(Me)₂CH₂CH₂Si(OMe)₃

(where Me represents a methyl group).

Furthermore, component (F) in the present invention can be and is preferably a reaction mixture of epoxy group-containing organoalkoxysilane and amino group-containing organoalkoxysilane disclosed in Japanese Examined Patent Publication S52-8854 and Japanese Unexamined Patent Application H10-195085, and particularly carbasilatrane derivatives having a silicon atom-bonded alkoxy group or silicon atom-bonded alkenyl group in one molecule, silatrane derivatives having an alkoxysilyl group-containing organic group, and the like in addition to 3-glycidoxypropyltrimethoxysilane and other silane compounds, organosiloxane oligomers, and alkyl silicates. Note that these are also disclosed in the Patent Documents 1 to 4 above, and an appropriate adhesion imparting agent can be selected therefrom.

### [(A′) Chain Organopolysiloxane not Containing a Carbon-Carbon Double Bond-Containing Reactive Group in a Molecule]

A non-reactive organopolysiloxane, such as polydimethylsiloxane, polydimethyldiphenylsiloxane, or the like that does not contain a carbon-carbon double bond-containing reactive group such as alkenyl groups, acryl groups, and methacryl groups, and the like, can be added to the curable organopolysiloxane composition according to the present invention groups, which may make it possible to improve the loss coefficient (tan δ), storage elastic modulus (G′), and loss modulus (G″) of the cured product. For example, the loss coefficient of the cured product can be increased by using a polydimethylsiloxane or polydimethyldiphenylsiloxane having a hydroxyl group end, with such compositions included within the scope of the present invention.

### [Organic Solvent]

The hot-melt curable organopolysiloxane composition according to the present invention is solid at 25° C. or has inferior fluidity, and thus is essentially a low-solvent or solvent-free composition. On the other hand, a small amount of organic solvent may be included if unavoidably included in order to improve the wettability of the present composition to the base material, or as a solvent associated with component (B). Furthermore, if each component must be uniformly mixed or if the present composition must be coated in order to obtain a hot-melt curable organopolysiloxane composition in sheet or film form as described later, the hot-melt curable organopolysiloxane composition according to the present invention may be temporarily mixed with one or more organic solvents dispersed as a diluent or dispersant, and may further be coated in film or sheet form in the form of a dispersion. In this case, the organic solvent is preferably removed from the final mixed composition, which is the composition formed into film or sheet form, by heating and drying or other means, so as to achieve a solid form.

When the hot-melt curable organopolysiloxane composition is dispersed in an organic solvent as the diluent or dispersant described above, with the total amount (=sum) of components (A) to (D) and other optional nonvolatile components that form the solid fraction of a cured product being 100 parts by mass, the total amount of the organic solvent as a diluent is within the range of 0 to 100 parts by mass, and preferably 0 to 25 parts by mass.

Examples of organic solvents used as diluents or dispersants during coating/uniform mixing include: toluene, xylene, benzene, and other aromatic hydrocarbon-based solvents; heptane, hexane, octane, isoparaffin, and other aliphatic hydrocarbon-based solvents; ethyl acetate, isobutyl acetate, and other ester-based solvents; diisopropyl ether, 1,4-dioxane, and other ether-based solvents; trichloroethylene, perchloroethylene, methylene chloride, and other chlorinated aliphatic hydrocarbon-based solvents; solvent volatile oils; and the like, with two or more types thereof capable of being combined in accordance with the wettability of the sheet-like base material or the like.

The hot-melt curable organopolysiloxane composition according to the present invention may optionally contain components other than the components described above to an extent that does not impair the technical effects of the present invention. For example, the composition may contain: an adhesion promoter; an antioxidant such as a phenol-type, a quinone-type, an amine-type, a phosphorus-type, a phosphite-type, a sulfur-type, or a thioether-type antioxidant; a light stabilizer such as triazoles or benzophenones; a flame retardant such as a phosphate ester-type, a halogen-type, a phosphorus-type, or an antimony-type flame retardant; and one or more types of antistatic agents including cationic surfactants, anionic surfactants, non-ionic surfactants, and the like; a polymerization inhibitor; a UV absorber; or the like. Note that in addition to these components, pigments, dyes, inorganic microparticles that may be optionally surface-treated (reinforcing fillers, dielectric fillers, electrically conductive fillers, thermally conductive fillers), and the like can also be optionally added.

The method of preparing the hot-melt curable organopolysiloxane composition according to the present invention is not particularly limited and is performed by homogeneously mixing the respective components. An organic solvent may be added as necessary, and the composition may be prepared by mixing using a known stirrer or kneader. Note that depending on the type of component (C), the present composition may have radical polymerizing properties when heated, and thus in such cases, mixing is preferred at a temperature less than 200° C., and preferably less than 150° C.

The hot-melt curable organopolysiloxane composition of the present invention may be used in the form of granules, pellets, sheets, films, or the like.

When the present composition is formed in sheet or film, the sheet or film made from the curable silicone composition of the present invention with an average thickness of 10 to 1000 μm has hot-melt properties and, depending on the type of component (B), is curable by a radical polymerization reaction triggered by high-energy beam irradiation or heating. Therefore, the sheet or film has excellent handling workability and melting properties, and is particularly advantageous for use in overmolding, film adhesives between base materials, and the like.

### [Laminate Body Containing Hot-Melt Curable Organopolysiloxane Composition and Use Thereof as Film Adhesive/Sealing Agent]

The hot-melt curable organopolysiloxane composition of the present invention can be used in a sheet or film form, and can be particularly used as a laminate body having a structure in which a sheet-like material containing the composition described above is interposed between two film-like base materials provided with a release layer. The film-like base material provided with the release layer (generally referred to as release film) can be released from the sheet-like material containing the hot-melt curable organopolysiloxane composition when the sheet-like material is used as an adhesive, sealing agent, or the like. The laminate body is also referred to as a releasable laminate body below.

The sheet or film of the hot-melt curable organopolysiloxane composition can be obtained by the following:
Step (I): a step of applying the hot-melt curable organopolysiloxane composition described above on a base material; and
Step (II): a step of heating and drying the composition applied in step (I) to obtain a composition formed into a sheet or film.
   Herein, when applying the hot-melt curable organopolysiloxane composition in step (I), the composition may be applied on the base material in a fluid state by heating and melting the composition itself, or may be applied on the base material in the form of a dispersion solution using an organic solvent, with the organic solvent being removed in step (II). Note that if a release layer is present on the base material, the sheet or film of the curable hot-melt silicone composition can be obtained as part of a releasable laminate body described next. Note that depending on the type of component (C), the present composition may have radical polymerizing properties when heated, and thus in such cases, heating and drying is particularly preferably performed at a temperature less than 150° C.

The method of manufacturing the releasable laminate body is not particularly limited, and an example thereof includes a method including: Step 1: a step of mixing a component of the hot-melt curable organopolysiloxane composition described above;
Step 2: a step of kneading the mixture obtained in step 1 while heating and melting;
Step 3: a step of laminating the heated and melted mixture obtained in step 2 between two release films provided with at least one release surface, such that the mixture contacts the release surface, to form a laminate body; and
Step 4: a step of pressing the laminate body obtained in step 3 between rollers and rolling the mixture interposed between the two release films to form a hot-melt curable organopolysiloxane composition sheet or film having a specific thickness.
   Furthermore, rollers with a cooling or temperature adjusting function may be optionally used in step 4. Furthermore, after step 4, a step may be added of cutting the laminate body containing the resulting hot-melt curable organopolysiloxane composition sheet or film. Furthermore, instead of step 2, the mixture obtained in step 1 may be applied to the release film in the form of a dispersion in an organic solvent, and the organic solvent may be removed by heating or the like prior to step 3.

Note that the thickness of the release film is not particularly limited, and therefore, in addition to those generally referred to as a film, those referred to as a sheet are also included. However, in the present specification, it is referred to as a release film regardless of the thickness thereof.

The temperature of the mixing step of step 1 above is not particularly limited, but each component may be heated as necessary to ensure sufficient mixing, and the heating temperature can be 50° C. or higher, for example.

The release film is released from the releasable laminate body of the present invention to obtain a sheet or film made of the hot-melt curable organopolysiloxane composition. Therefore, the present invention also provides such a sheet or film. The sheet or film of the present invention is preferably 10 to 1000 μm thick, and the sheet or film is preferably flat. Flat means that the thickness of the resulting sheet or film is within ±100 μm or less, preferably within ±50 μm or less, more preferably within ±30 μm or less.

The type of base material of the release film configuring the releasable laminate body is not limited, but a polyester film, a polyolefin film, a polycarbonate film, acrylic film, or the like, for example, can be used as appropriate. The sheet-like base material is preferably non-porous. A release film is a film having a release layer formed by treating one or both surfaces of a film made of such a material to impart release properties, and such treatments are known in the field.

The release layer is a releasable layer applied to the surface of a release film. Moreover, the release layer is a structure that allows a sheet or film made of a curable silicone composition to be easily released from a film-like base material, and is sometimes referred to as a release liner, separator, mold release layer or release coating layer. Preferably, the release layer can be formed as a release layer with release coating capability such as a silicone release agent, a fluorine release agent, an alkyd release agent, a fluorosilicone release agent, or the like. Alternatively, the surface of the film-like base material may be physically formed with microscopic irregularities to reduce the adhesion strength to the hot-melt curable organopolysiloxane composition, or the base material may be made of a material that is difficult to adhere to a layer made of the composition of the present invention or a cured product thereof. In particular, the use of a release layer obtained by curing a fluorine release agent or fluorosilicone release agent as the release layer is preferred in the laminate body of the present invention.

For the laminate body, for example, one of the two release films configuring the laminate body can be released, an uncured sheet or film member containing the hot-melt curable organopolysiloxane composition that is not in contact with the release film can be applied to an adherend, and then the uncured sheet or film member can be used so as to release from another film-like base material, such as a release film.

The hot-melt curable organopolysiloxane composition can be handled in granular, pellet or sheet form at room temperature and is a low-fluid or a non-fluid solid at 25° C. Herein, non-fluidity means that the curable silicone composition does not deform and/or flow in the absence of an external force, and preferably, the curable silicone composition does not deform and/or flow at 25° C. and in the absence of an external force when molded into pellets or tablets. Such non-fluidity can be assessed, for example, by placing the molded composition on a hot plate at 25° C. and applying no external force or a certain amount of weight to the composition, and making sure substantial deformation and/or flow of the composition does not occur. If the composition is non-fluid at 25° C., handling even in an uncured state is simple because shape retention of the composition is favorable at that temperature and the surface pressure-sensitive adhesion thereof is low.

The softening point of the present composition is preferably 100° C. or lower. Such a softening point means the temperature at which the deformation amount of the composition in the height direction is 1 mm or more when the composition is pressed for 10 seconds from above with a 100 gram load at a height of 22 cm on a hot plate and then the deformation of the composition is measured after the load is removed.

### [Hot-Melt Curable Organopolysiloxane Composition Sheet]

The sheet obtained by the manufacturing method of the present invention is a hot-melt curable organopolysiloxane composition containing the aforementioned components and has hot-melt properties. The curable hot-melt silicone composition sheet of the present invention can be used as a pressure-sensitive adhesive material, sealing agent, and/or adhesive, or the like, having heat-melting properties. In particular, the curable hot-melt silicone composition sheet has excellent moldability, gap-filling properties, and pressure-sensitive adhesive strength, and can be used as a die-attach film or film adhesive. Furthermore, it can be suitably used as a hot-melt curable organopolysiloxane composition sheet for overmolding, compression molding or press molding, and may be suitably used as an elastic pressure-sensitive adhesive member between base materials of a semiconductor or the like.

Specifically, the hot-melt curable organopolysiloxane composition sheet obtained by the manufacturing method of the present invention can be peeled from a release film, then disposed at a desired site on a semiconductor or the like, and melted by heat to form, on and between adherends, a film adhesive layer utilizing gap-filling properties with regard to protrusions and recesses or gaps on a base material, followed by being temporarily secured, disposed, and applied together between the adherends. Furthermore, the uncured composition layer can be cured by one or more radical polymerization reactions selected from (i) heat curing reactions and (ii) photocuring reactions by high-energy beam irradiation, and a cured product of the curable silicone sheet can be formed between the adherends to adhere the adherends. Note that the release film may be released after the curable hot-melt silicone composition sheet is heated to form a cured product, and a timing for releasing the release film from the curable silicone composition or cured product obtained therefrom may be selected based on the application and method of use of the curable silicone composition sheet.

The curable organopolysiloxane composition has hot-melt properties. Therefore, the sheet can be softened or fluidized by heating prior to final curing, for example, to form an adhesive surface with an adherend by filling protrusions and recesses or gaps without a void even if there are irregularities on the adhesive surface of the adherend. Examples of heating means of the sheet that can be used include various thermostatic baths, hot plates, electromagnetic heating devices, heating rollers, and the like. In order to more efficiently adhere the adherend and curable silicone composition sheet together and heat the curable silicone composition, an electric heating press, a diaphragm type laminator, a roll laminator, or the like is preferably used, for example.

### [Method of Forming Cured Product]

As already mentioned, the hot-melt curable organopolysiloxane composition according to the present invention can be designed as a photocurable composition by high-energy beam irradiation, or as a heat-curable composition by heating, based on the selection of component (C).

When at least part of component (C) is the photoradical polymerization initiator (C1), the curable silicone composition of the present invention can form a cured product by irradiating the composition (or semi-cured product thereof) with a high-energy beam of UV rays or the like, which causes a radical polymerization reaction to proceed.

Examples of available high-energy beams include UV rays, gamma rays, X-rays, alpha rays, electron beams, and the like. Particular examples include UV rays, X-rays, and electron beams irradiated from a commercially available electron beam irradiating device, with UV rays preferred for practical use. As the UV-generating source, a high-pressure mercury lamp, a medium-pressure mercury lamp, a Xe—Hg lamp, a deep UV lamp, or the like is suitable. In particular, UV irradiation with a wavelength of 280 to 400 nm, and preferably 300 to 400 nm, is preferred, and a light source with a plurality of light emission bands may be used.

Although the high-energy beam irradiation dose varies depending on the type and amount of the photoradical polymerization initiator (C1) and the degree of curing reaction, when UV rays are used, the cumulative irradiation dose at a wavelength of 365 nm is preferably within the range of 100 mJ/cm² to 100 J/cm². Note that the high-energy beam irradiation may be performed with the base material sandwiched in between, so long as the base material supporting the pressure-sensitive adhesive layer according to the present invention does not absorb electromagnetic waves in the wavelength region above. In other words, if a certain amount of irradiation is feasible, high-energy beam irradiation may be performed over a cover material such as a base material, protective film, or the like.

The curing reaction does not require heating, and therefore curing can be performed at a low temperature (15 to 100° C.), including room temperature (25° C.). Note that in an embodiment of the present invention, “low temperature” refers, for example, to 100° C. or lower, specifically, a temperature range of 15° C. to 100° C., and even temperatures of 80° C. or lower can be selected. When the reaction of the composition (including a semi-cured product) of the present invention proceeds in the temperature range of 15 to 100° C., the present composition may suitably be left at or near room temperature range (a temperature range that can be reached without heating or cooling, particularly including a temperature region of 20 to 25° C.), may be cooled to 15° C. to room temperature, or may be heated to room temperature or higher and 100° C. or lower. Note that the time required for the curing reaction can be designed as appropriate according to the irradiation dose of a high-energy beam of UV rays or the like and the temperature. Furthermore, the irradiation may be interrupted before reaching a prescribed cumulative irradiation dose to obtain a cured product in the form of a semi-cured product that retains photocuring reactivity. Furthermore, depending on process acceptability and necessity, heating above 100° C. may be temporarily performed, or heating and crimping may be performed at the same time to allow the curing reaction to proceed simultaneously with crimping.

When at least part of component (C) includes the thermal radical polymerization initiator (C2), the curable silicone composition of the present invention can form a cured product by heating to 100° C. or higher, which causes a radical polymerization reaction to proceed. The heating temperature can be selected in accordance with the heat resistance of the base material, sealing process, and the like. If the base material has high heat resistance, heating at a high temperature of 150° C. or higher can be performed.

The cured product of the hot-melt curable organopolysiloxane composition of the present invention has practical resistance to yellowing under high temperature, high humidity, or UV exposure conditions and excellent transparency. In other words, the present composition can be used to obtain a cured product with a b* value of 2.0 or less, and preferably 1.0 or less after 500 hours when the thickness of the cured product is 200 um in a high temperature exposure test at 100° C. or in an accelerated weathering test in accordance with ASTM G 154 Cycle 1 (hereinafter, QUV test). In particular, with a conventionally known active energy ray-curable hot-melt silicone composition that can be cured at low temperatures (e.g., the aforementioned Patent Document 2 and the like), the resistance of a cured product to yellowing is low, making it difficult to apply in applications where transparency is required. However, the cured product according to the present invention has practical yellowing resistance and high transparency, while allowing rapid curing at low temperatures as needed, and thus has the advantage of being suitable for optical material applications, including optical semiconductor sealing agents. The composition according to the present invention is also suitable for use in applications where a base material with inferior heat resistance is sealed by a transparent cured product.

### [Application of Composition]

The hot-melt curable organopolysiloxane composition of the present invention has hot-melt properties, excellent handling workability and curability while melted (hot-melted), excellent transparency in a resulting cured product obtained by curing the present composition, and excellent pressure-sensitive adhesive strength to a base material. Therefore, the composition is usefully used for sealing materials for light emitting/optical devices, pressure-sensitive adhesive members, light reflective materials and other semiconductor members, and optical semiconductors having the cured product. Furthermore, since the cured product has superior mechanical properties, the cured product is suitable as: a sealing agent for semiconductors; a sealing agent for power semiconductors such as SiC, GaN, or the like; and as an adhesive, potting agent, protective agent, and coating agent for electrical and electronic applications. The curable hot-melt silicone composition of the present invention in sheet form is also suitable as a material for sealing and adhering large-area substrates using press molding, compression molding, a vacuum laminator, or the like. In particular, the composition is preferably used as a sealing agent for semiconductors using an overmolding method at the time of molding. Furthermore, a sheet of the present composition can be used as a curable film adhesive or as a buffer layer for stress between two base materials with different coefficients of linear expansion.

Furthermore, the hot-melt curable organopolysiloxane composition of the present invention, and particularly the hot-melt curable organopolysiloxane composition in a sheet form, can be used for large area sealing of a semiconductor substrate (including wafers). Furthermore, a sheet formed from the curable hot-melt silicone composition of the present invention can be used for die-attach films, sealing a flexible device, stress relief layers for adhering two different base materials, and the like. In other words, the curable silicone composition of the present invention may be a sealing agent for single-sided sealing or for double-sided sealing along with adhesion between two base materials, and has preferred properties suitable for these applications.

### [Application of Cured Product]

An application of the cured product obtained by curing the hot-melt curable organopolysiloxane composition of the present invention is not particularly limited. The composition of the present invention has hot-melt properties, excellent curability, excellent moldability and mechanical properties, and a cured product thereof has practical resistance to yellowing and maintains high transparency. Therefore, the cured product obtained by curing the present composition can be suitably used as a member for a semiconductor device, and can be suitably used as a sealing material for a semiconductor element, IC chip, or the like, and as a pressure-sensitive adhesive, adhesive, bonding member, and other adhesive members for a conductor device. In particular, the cured product can be designed to achieve a very wide range of adhesive strengths between a surface thereof and a base material, and can be used in a variety of applications. Specifically, the cured product according to the present invention has low surface tackiness and excellent mold-releasability of a cured layer, and thus can be designed with a wide range of adhesion properties and adhesive capabilities, such as cured products that are suitable for sealing agent applications, cured products in which the mode of release to a base material in contact during curing is interfacial peeling, and cured products that form a permanent adhesive/joint body in conjunction with cohesive breakdown of the cured product in the mode of release to a base material in contact during curing. Herein, in order to improve the adhesion properties of an adherend and the cured product, the cured product or a base material may be subjected to a surface treatment such as a primer treatment, corona treatment, etching treatment, plasma treatment, or the like. Furthermore, in the case above, the cured product surface that is not in contact with the base material can be designed to have adhesion properties to another base material, and therefore, the cured product surface can be and preferably is used as a pressure-sensitive adhesive surface, tacky surface or adhesive surface.

Although a semiconductor device provided with a member containing a cured product obtained by curing the hot-melt curable organopolysiloxane composition of the present invention is not particularly limited, the composition of the present invention forms an optically transparent cured product, and thus is particularly preferably used in applications that require light transmission. For example, it is preferably a light-emitting semiconductor device, which is a light-emitting/optical device, optical member for a display, a solar panel member, and particularly a sealing material or adhesive member used in these devices and the like. Furthermore, the cured product of the present invention is more preferably used as a sealing material or adhesive member used in electronic materials where transparency and light/heat resistance are important.

### [Method of Sealing or Adhering Semiconductor Device or the Like]

The hot-melt curable organopolysiloxane composition according to the present invention is preferably used in a method of sealing or adhering a semiconductor device or optical semiconductor device, the method including the following:
Step (E-1): a step of closely attaching the hot-melt curable organopolysiloxane composition according to the present invention to some or all of a base material, which is a semiconductor device, an optical semiconductor device, or a precursor thereof; and
Step (E-2): a step of curing the hot-melt curable organopolysiloxane composition by one or more curing reactions selected from (i) heat curing reactions and (ii) photocuring reactions by irradiation with a high-energy beam.

As a step prior to step (E-1), the hot-melt curable organopolysiloxane composition according to the present invention is made to flow by heating to fill protrusions and recesses or voids on a base material serving as a semiconductor device, optical semiconductor device, or precursor thereof, such that a cured product with excellent gap-filling properties between base materials can seal or adhere the semiconductor device or optical semiconductor device.

### Examples

Hereinafter, the present invention is described in detail with reference to the examples and comparative examples, but the present invention is not limited to the following examples.

### (Measurement of Molecular Weight of Organopolysiloxane Component)

Using gel permeation chromatography (GPC) available from Waters and tetrahydrofuran (toluene) as a solvent, the weight average molecular weight (Mw) and number average molecular weight (Mn) of organopolysiloxane components such as organopolysiloxane resin were determined in terms of standard polystyrene.

### (Preparation of Curable Silicone Composition)

Curing-reactive organopolysiloxane compositions indicated in the examples and comparative examples in Table 1 were prepared as xylene solutions with a solid fraction of 70% using each of the components listed below. Note that all percentages in this table refer to mass %. Furthermore, the viscosity and plasticity of each component are values measured at 25° C.
(A1) Dimethylsiloxane/(5-hexenyl)methylsiloxane copolymer raw rubber with a plasticity of 125 and blocked at both ends by trimethylsiloxy groups (amount of vinyl groups: 0.79 mass %)
(A2) Dimethylsiloxane/methylvinylsiloxane copolymer raw rubber with a plasticity of 120 and blocked at both ends by trimethylsiloxy groups (amount of vinyl groups: 0.84 mass %)
(A3): Dimethylsiloxane polymer with a viscosity of 37 Pa·s and blocked at both ends with dimethylvinylsiloxy groups (amount of vinyl groups: 0.10 mass %)
(B1) Organopolysiloxane resin containing in a molecule a siloxane unit (M unit) expressed by Me₃SiO_{1/2} and a siloxane unit (Q unit) expressed by SiO_{4/2} at a molar ratio of 1.0:1.0 (weight average molecular weight (Mw) of 7,000, as measured by GPC using toluene as a solvent)
(B2) Organopolysiloxane resin containing in a molecule a siloxane unit (M unit) expressed by Me₂RSiO_{1/2} (R represents a methyl group or vinyl group) and a siloxane unit (Q unit) expressed by SiO_{4/2} at a molar ratio of 1.0:1.0 (amount of vinyl groups: 1.90 mass %; weight average molecular weight (Mw) of 8,000, as measured by GPC using toluene as a solvent)
(C1-1) 2,4,6-trimethylbenzoyldiphenylphosphine oxide (product name: Omnirad TPO-L, manufactured by IGM Resins Co., Ltd.)
(D1-1) Dodecyl acrylate (manufactured by Tokyo Chemical Industry Co., Ltd.)
(D1-2) 1,3-butanediol dimethacrylate (manufactured by Wako Pure Chemical Industries, Ltd.)
(D1-3) 1,12-bis(methacryloyloxy) dodecane (manufactured by Tokyo Chemical Industry Co., Ltd.)
(D1-4) Triethylene glycol di(meth)acrylate (manufactured by Tokyo Chemical Industry Co., Ltd.)
(D1-5) Polyethylene glycol di(meth)acrylate (average degree of polymerization: 9) (manufactured by Tokyo Chemical Industry Co., Ltd.)
(D2-1) Dimethylsiloxane polymer with blocked at both ends with dimethyl(acryloyloxyoctyl)siloxy groups (amount of C₃H₃O₂:8.43 mass %)
(D2-2) Dimethylsiloxane-methyl {6-[3-(3-methacryloyloxypropyl)-1,1,3,3-tetramethyldisiloxy]hexenyl}siloxane polymer blocked at both ends with trimethylsiloxy groups (amount of C₄H₅O₂ groups: 2.49 mass %)

### (Amount of Component (B) in Composition: Resin Amount)

The synthetic mass percentage of component (B) to the total mass of the solid fraction (components that form the cured product, excluding organic solvents) of each composition is defined as the amount of component (B), and is listed in Table 1 as the “resin amount” (unit: mass %).

### (Resin/Polymer Ratio of Composition)

With the total mass percentage of component A as “a,” the synthetic mass percentage of component B as “b,” and the total mass percentage of component D2 as “d2” with respect to the entire mass of solid fractions (components that form the cured product, excluding organic solvents) in each composition, the resin/polymer ratio of the composition is the mass ratio defined by “b/(a+d2)” and is shown in Table 1.

### (Complex Viscosity of Curable Composition)

A film-like pre-cured composition with a thickness of 200 microns was placed in close contact between a shear rotation jig and sample stage, and shear stress was applied to the sample (shear strain: 0.05%, frequency: 1 Hz) while the sample temperature was increased from 25° C. to 100° C. at a rate of 2° C./min using MCR302 manufactured by Anton Paar, to measure the complex viscosity. The unit of the complex viscosity in Table 1 is 10³ Pa·s, and the rate of change in viscosity is the ratio of the complex viscosity at 80° C. to the complex viscosity at 25° C. expressed as a percentage.

### (Film Preparation of UV-Curable Composition)

Each composition was coated on a PET film (Lumirror (registered trademark) S10 manufactured by Toray, thickness: 50 μm) such that the thickness after curing is 55 μm, dried in an oven at 100° C. for 10 minutes, and cooled at room temperature, and then the surface of the composition is covered by a release film (FSC-6 manufactured by NIPPA, thickness: 50 μm) to prepare a release film laminate body. Using a UV-LED UV irradiating device (manufactured by JATEC), the composition was cured by irradiating UV rays with a wavelength of 405 nm from the PET film side such that the UV irradiation dose (illumination intensity) was 4,000 mJ/cm² as an integrated light amount. The sample was cut to 25 mm in width, the release film was peeled off, and the cured composition surface was adhered to a SUS plate (manufactured by PALTEC) using a roller to obtain a test piece. Table 1 shows the pressure-sensitive adhesive strength (gf/25 mm) of the test piece, which was measured using a 180° peel test method in accordance with JIS Z 0237 at a tensile rate of 300 mm/min. The breaking mode in the peeling measurement was classified as “AF” when the composition peeled off at the interface between the composition and SUS, and “CF” when the composition itself was destroyed. Furthermore, test pieces with low workability of the release film laminate body described below were not subjected to the peel test and were designated as “NG”.

### (Workability Evaluation of Release Film Laminate Body)

Release film laminate bodies containing a film of the uncured UV-curable composition were prepared for Examples 1 to 10 and Comparative Examples 1 and 2 in the same manner as described above (Film preparation of UV-curable composition). When the film of the UV-curable composition was peeled off from the release film without UV irradiation, it was confirmed that for Examples 1 to 10, the film of the UV-curable composition could be peeled from the release layer at the interface without causing damage or the like, and that workability was favorable. On the other hand, for Comparative Examples 1 and 2, when the film of the UV-curable composition was peeled from the release film, parting and damage of the UV-curable composition film occurred in the mold release layer, and interfacial peeling could not be performed.

### (Appearance and Measurements of Cured Product)

Each composition was applied to a release film (FSC-6 manufactured by NIPPA, thickness: 50 μm) to a post-curing thickness of 200 μm, and then dried in an oven at 100° C. for 10 minutes. Test pieces were prepared by laminating two alkali-free glass plates (manufactured by Corning) with the film composition, irradiating with UV rays with a wavelength of 405 nm such that the UV irradiation dose (illumination intensity) was 4,000 mJ/cm² as an integrated light amount, and then curing the composition. After two hours, the haze values of the test pieces were measured using a spectrophotometer CM-5 (manufactured by Konica Minolta). Haze values of less than 1 were classified as “∘”, and haze values of 1 or more were classified as “x”.

TABLE 1

| Test No. | Example | Example | Example | Example | Example | Example | Example |
|---|---|---|---|---|---|---|---|
| /Component | 1 | 2 | 3 | 4 | 5 | 6 | 7 |
| A1 | 12.9 | 30.7 | | 23.8 | 27.8 | 27.7 | |
| A2 | | | 23.8 | | | | |
| A3 | | | | | | | 5.9 |
| B1 | 70.3 | 58.4 | 69.3 | 69.3 | 69.7 | 69.3 | 61.4 |
| B2 | | | | | | | 16.8 |
| C1-1 | 1 | 1 | 1 | 1 | 0.5 | 1 | 1 |
| D1-1 | | | | 5.9 | | | |
| D1-2 | | | 5.9 | | | | |
| D1-3 | | | | | 2 | 2 | |
| D1-4 | | | | | | | |
| D1-5 | | | | | | | |
| D2-1 | 15.8 | 9.9 | | | | | |
| D2-2 | | | | | | | 14.9 |
| Total | 100 | 100 | 100 | 100 | 100 | 100 | 100 |
| Curability | ◯ | ◯ | ◯ | ◯ | ◯ | ◯ | ◯ |
| Resin/polymer | 2.4 | 1.4 | 2.9 | 2.9 | 2.5 | 2.5 | 3.8 |
| ratio | | | | | | | |
| Complex | 49.4 | 0.5 | 1450 | 451 | 151 | 141 | 178 |
| viscosity | | | | | | | |
| before | | | | | | | |
| curing at | | | | | | | |
| 25° C. | | | | | | | |
| Complex | 0.9 | 0.1 | 228 | 17.1 | 4.2 | 2.5 | 16.6 |
| viscosity | | | | | | | |
| before curing | | | | | | | |
| at 80° C. | | | | | | | |
| Viscosity | 98.2% | 80.0% | 84.3% | 96.2% | 97.2% | 98.2% | 90.7% |
| change rate | | | | | | | |
| Resin amount | 70% | 58% | 69% | 69% | 70% | 69% | 78% |
| mass % | | | | | | | |
| Pressure- | 5 | 950 | 2417 | 1167 | 3108 | 3658 | 1883 |
| sensitive | | | | | | | |
| adhesive | | | | | | | |
| strength | | | | | | | |
| gf/25 mm | | | | | | | |
| Breaking | AF | AF | CF | CF | CF | CF | CF |
| mode | | | | | | | |
| Appearance | ∘ | ∘ | ∘ | ∘ | ∘ | ∘ | ∘ |
| of cured | | | | | | | |
| product | | | | | | | |

| Test No. | Example | Example | Example | Comparative | Comparative |
|---|---|---|---|---|---|
| /Component | 8 | 9 | 10 | Example 1 | Example 2 |
| A1 | 28.2 | 24.8 | 25.6 | | 44.6 |
| A2 | | | | 39.6 | |
| A3 | | | | | |
| B1 | 70.8 | 71.7 | 71.8 | 49.5 | 44.6 |
| B2 | | | | | |
| C1-1 | 1 | 0.5 | 0.5 | 1 | 1 |
| D1-1 | | | | | |
| D1-2 | | | | | |
| D1-3 | | 2 | 2 | | |
| D1-4 | | 1 | | | |
| D1-5 | | | 0.1 | | |
| D2-1 | | | | 9.9 | 9.9 |
| D2-2 | | | | | |
| Total | 100 | 100 | 100 | 100 | 100 |
| Curability | ◯ | ◯ | ◯ | ◯ | ◯ |
| Resin/polymer | 2.5 | 2.9 | 2.8 | 1 | 0.8 |
| ratio | | | | | |
| Complex | 339 | 263 | 451 | 1 | 0.2 |
| viscosity | | | | | |
| before | | | | | |
| curing at | | | | | |
| 25° C. | | | | | |
| Complex | 41 | 6.7 | 18 | 0.4 | 0.1 |
| viscosity | | | | | |
| before curing | | | | | |
| at 80° C. | | | | | |
| Viscosity | 87.9% | 97.5% | 96.0% | 60.0% | 50.0% |
| change rate | | | | | |
| Resin amount | 71% | 72% | 72% | 50% | 45% |
| mass % | | | | | |
| Pressure- | 1700 | 1900 | 3300 | NG | NG |
| sensitive | | | | | |
| adhesive | | | | | |
| strength | | | | | |
| gf/25 mm | | | | | |
| Breaking | AF | CF | CF | NG | NG |
| mode | | | | | |
| Appearance | ∘ | ∘* | ∘* | ∘ | ∘ |
| of cured | | | | | |
| product | | | | | |

*The haze value remained at 1 or more even under high humidity and dry conditions.

As shown in Table 1, the hot-melt curable organopolysiloxane compositions of the present invention according to Examples 1 to 10 are solid to substantially non-fluid at room temperature (25° C.), but can achieve a melt viscosity suitable for sealing and adhering with a viscosity change exceeding 80% at 80° C. Moreover, cured products obtained by photoradical polymerization reaction have excellent transparency and a wide range of pressure-sensitive adhesive strength that is sufficient for practical use on base materials. For example, the compositions of Example 1 and the like are expected to be suitable for forming transparent sealing layers with excellent gap-filling properties and no surface stickiness, because cured products thereof after hot-melting have low tack and excellent mold release properties (interfacial peeling). On the other hand, the cured products of the compositions of Example 3 and the like after hot-melting have strong adhesive strength and cohesive failure at break, and thus are useful not only as a permanent adhesive and joining layer between base materials, but also for using a cured product containing the present composition as an adhesive surface tightly bonded to the base material by forming the cured product on only one surface of the base material, and the like. Furthermore, the cured products according to Examples 9 and 10 had favorable haze resistance properties, with haze values maintained at 1 or more even under high humidity and dry conditions.

From these properties, the hot-melt curable organopolysiloxane composition according to the present invention, when used in the manufacturing process of display devices, electronic devices, or the like including a base material with low stability at high temperatures, are expected to have excellent sealing performance and adhesion at 80° C., be curable at room temperature by high-energy beam irradiation, and obtain a cured product with excellent appearance stability and transparency.

On the other hand, when the amount of component (B) was low and the resin/polymer ratio in the composition was 1 or less, as in Comparative Examples 1 and 2, the compositions lacked workability and did not achieve practical hot-melt properties.

1. A hot-melt curable organopolysiloxane composition, comprising:
(A) 1 to 50 parts by mass of a chain organopolysiloxane having two or more alkenyl groups in a molecule;
(B) 50 to 99 parts by mass of an organopolysiloxane resin containing a siloxane unit (M unit) expressed by R₃SiO₁₂ where R mutually independently represents a monovalent organic group and a siloxane unit (Q unit) expressed by SiO_{4/2} in a molecule, and in which the molar ratio of M units to 1 mol of Q units is in the range of 0.5 to 2.0;
(C) 0.1 to 10 parts by mass of a radical polymerization initiator; and
(D) 0 to 50 parts by mass of one or more type of radical reactive component selected from component (D1) and component (D2) below;
(D1) monofunctional or polyfunctional vinyl monomers, and
(D2) organopolysiloxane compounds having an organic group having at least one of an acryl or methacryl group in a molecule; wherein
the amount of component (B) is 50 mass % or more with respect to the total mass of the solid fraction of the composition, and the ratio of the mass of component (B2) to the sum of the masses of component (A) and component (D2) is greater than 1.0.

2. The hot-melt curable organopolysiloxane composition according to claim 1, wherein at least a portion of component (D) is (D1-1) a monofunctional or polyfunctional vinyl monomer having 8 to 30 carbon atoms.

3. The hot-melt curable organopolysiloxane composition according to claim 1, wherein at least a portion of component (D) is (D2-1) a chain organopolysiloxane having at least one silicon atom-bonded functional group R^{A} expressed by 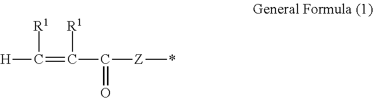
where R¹ mutually independently represents a hydrogen atom, a methyl group, or a phenyl group, and Z represents a divalent organic group which may contain a hetero atom and is bonded to a silicon atom configuring a main chain of a polysiloxane represented by *
at an end or in a side chain of a molecular chain.

4. The hot-melt curable organopolysiloxane composition according to claim 1, wherein at least a portion of component (C) is (C1) a photoradical polymerization initiator and is photocurable by high-energy beam irradiation.

5. The hot-melt curable organopolysiloxane composition according to claim 1, wherein at least a portion of component (C) is (C2) a thermal radical polymerization initiator and is heat-curable.

6. The hot-melt curable organopolysiloxane composition according to claim 1, wherein the complex viscosity of the pre-cured composition at 80° C. is 500,000 Pa·s or less.

7. A cured product obtained by curing or semi-curing the hot-melt curable organopolysiloxane composition according to claim 1.

8. The hot-melt curable organopolysiloxane composition according to claim 1, which is molded into a sheet or film.

9. A releasable laminate body, comprising:
a sheet or film of the hot-melt curable organopolysiloxane composition according to claim 8; and
a sheet-like or film-like base material provided with a release surface adhered to one surface or both surfaces of the composition sheet or film, and facing the composition sheet or film; wherein
the composition sheet or film can be released from the sheet-like or film-like base material provided with the release surface.

10. A semiconductor device or optical semiconductor device, comprising the cured product according to claim 7.

11. A method for manufacturing a sheet or film of the curable hot-melt silicone composition according to claim 8, the method comprising:
step (I): a step of applying onto a base material the hot-melt curable organopolysiloxane composition, optionally in the form of a dispersion in an organic solvent; and
step (II): a step of heating and drying the composition applied in step (I) to obtain a composition formed into a sheet or film.

12. A method for sealing or adhering a semiconductor device or optical semiconductor, the method comprising:
step (E-I): a step of closely contacting the hot-melt curable organopolysiloxane composition according to claim 1 to some or all of a base material, which is a semiconductor device, an optical semiconductor device, or a precursor thereof; and
step (E-2): a step of curing the hot-melt curable organopolysiloxane composition by one or more curing reactions selected from (i) heat curing reactions and (ii) photocuring reactions by irradiation with a high-energy beam.
